(19) United States
(12) Patent Application Publication
(10) Pub. No.: US 2015/0276845 A1
(43) Pub. Date: Oct. 1, 2015

(54) CAUSALITY ENFORCEMENT FOR ELECTRICAL INTERCONNECTS THROUGH PERIODIC CONTINUATIONS

(71) Applicants: Lyudmyla L. Barannyk, Moscow, ID (US); Hazem A. Aboutaleb, Cairo (EG); Fred D. Barlow, Moscow, ID (US)

(72) Inventors: Lyudmyla L. Barannyk, Moscow, ID (US); Hazem A. Aboutaleb, Cairo (EG); Fred D. Barlow, Moscow, ID (US)

(73) Assignee: University of Idaho

(21) Appl. No.: 14/667,428

(22) Filed: Mar. 24, 2015

Related U.S. Application Data
(60) Provisional application No. 61/970,231, filed on Mar. 25, 2014.

(51) Int. Cl. G01R 31/04

(52) U.S. Cl. CPC G01R 31/04

(57) ABSTRACT

Causality evaluation for transfer functions representing the behavior of electrical interconnects of a system is provided herein. An initial transfer function can be received that represents the behavior of electrical interconnects of a system over an initial frequency range. A causal, periodic continuation can then be constructed based on the initial transfer function and one or more causality conditions. The continuation is periodic over an extended frequency range that is larger than the initial frequency range. At a plurality of frequencies, values for the initial transfer function and values for the continuation can be compared. The causality of the initial transfer function can be assessed based on the comparing.

### CROSS-REFERENCE TO RELATED APPLICATION

This application claims the benefit of U.S. Provisional Application No. 61/970,231 filed on Mar. 25, 2014 and titled “CAUSALITY ENFORCEMENT USING SVD-BASED FOURIER CONTINUATIONS FOR HIGH SPEED DIGITAL INTERCONNECTS,” which is incorporated herein by reference in its entirety.

### BACKGROUND

The design of electrical interconnects, including high-speed digital interconnects, that are common on chip and at the package level in digital systems, typically requires systematic simulations at different levels in order to evaluate the overall electrical system performance and avoid signal and power integrity problems. To conduct such simulations, suitable models are needed that capture the relevant electromagnetic phenomena that affect the signal and power quality. These models are often obtained either from direct measurements or electromagnetic simulations in the form of discrete port frequency responses that represent scattering, impedance, or admittance transfer functions or transfer matrices in scalar or multidimensional cases, respectively. Once frequency responses are available, a corresponding macromodel can be derived using several techniques such as vector fitting, orthonormal vector fitting, the delay extraction-based passive macromodeling, and others.

However, errors can contimate data, preventing derivation of an accurate model. These errors may be due, for example, to noise, inadequate calibration techniques, imperfections of the test set-up in case of direct measurements, approximation errors due to the meshing techniques, discretization errors, or errors due to finite precision arithmetic occurring in numerical simulations. Data are also typically available over a finite frequency range as discrete sets with a limited number of samples. Both contaminated data and limited data can affect performance of macromodels, resulting in non-convergence or inaccurate models. Often the underlying cause of such behavior is the lack of causality in a given set of frequency responses.

Transfer functions representing the behavior of electrical interconnects of a system are typically frequency domain functions. Assessment of the causality of the transfer functions typically involves converting the frequency responses of the transfer function to the time domain using the inverse discrete Fourier transform. This conventional approach suffers from the Gibbs phenomenon that occurs in functions that are not sufficiently smooth and are represented by a truncated Fourier series. Other conventional approaches involve analysis of causality in the frequency domain be computing the Hilbert transform of a transfer function over a finite domain, which results in significant boundary artifacts due to a lack of out-of-band frequency responses.

### SUMMARY

Accurate and robust techniques are described herein for assessing causality of network transfer functions given, for example, in the form of bandlimited discrete frequency responses. Such transfer functions are commonly used to represent the electrical response of electrical digital interconnects, including high-speed digital interconnects, used on chip and in electronic package assemblies. Network transfer functions thus serve as a model of the behavior of the electrical interconnects of the system. As used herein, “high-speed” refers to frequencies where the corresponding wavelength is short relative to the length of the conductor forming the interconnect. “High-speed” thus varies depending upon the length of the conductor, as is well understood in the art.

Even small errors in developing a model of the behavior of the interconnects can lead to non-causal behavior that does not accurately represent the electrical response and may lead to a lack of convergence in simulations that utilize these models. The described approaches are based on constructing causal Fourier continuations by imposing causality conditions such as Hilbert transform relations or Kramers-Krönig dispersion relations. Given a transfer function, non-periodic in general, the described approaches construct highly accurate Fourier series approximations on a given frequency interval by allowing the function to be periodic in an extended domain. The causality conditions (e.g., dispersion relations) are enforced spectrally. This eliminates the necessity of approximating the transfer function behavior at infinity and explicit computation of the Hilbert transform.

An error analysis of the approaches is provided and takes into account a possible presence of a noise or approximation errors in data. The developed error estimates can be used in verifying causality of the given data. The performance of the approaches was tested on several analytic and simulated examples that demonstrate an excellent accuracy and reliability of the described approaches in agreement with the obtained error estimates. Using the described approaches, very small localized causality violations with amplitudes close to machine precision can be detected.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

The foregoing and other objects, features, and advantages of the claimed subject matter will become more apparent from the following detailed description, which proceeds with reference to the accompanying figures.

### BRIEF DESCRIPTION OF THE DRAWINGS

FIG. 1 illustrates an example method of assessing causality of an initial transfer function representing the behavior of electrical interconnects of a system.

FIG. 2 illustrates an example method of assessing causality of an initial transfer function in which the initial transfer function is represented as a Fourier series over the extended frequency range.

FIG. 3 is an example system configured to evaluate causality of an initial transfer function representing the behavior of electrical interconnects of a system.

FIG. 4 illustrates an initial transfer function and its causal continuations for a two-pole example.

FIG. 5 illustrates the real part of the continuations shown in FIG. 4 over a wider domain.

FIG. 6 illustrates a plot of the errors for the initial transfer function and continuations shown in FIG. 4.

FIG. 7 illustrates a plot of the errors for the two-pole example with an introduced Gaussian perturbation.

FIG. 8 illustrates an initial transfer function and its continuations for an example with a finite element model of a DRAM package.

FIG. 9 illustrates a plot of the errors in the approximation of the S(100,1) port for the transfer function shown in FIG. 8.

FIG. 10 illustrates a norm of the errors shown in FIG. 9.

FIG. 11 illustrates a transfer function and its causal continuations for a transmission line example.

FIG. 12 illustrates a plot of the errors for the initial transfer function and continuations shown in FIG. 11.

FIG. 13 illustrates a non-causal transfer function for a delayed Gaussian example.

FIG. 14 illustrates the errors between the non-causal transfer function and its causal continuations shown in FIG. 13.

FIG. 15 illustrates a causal transfer function and its causal continuations with an increased t_{d}.

FIG. 16 illustrates the errors between the causal transfer function and its causal continuations shown in FIG. 15.

FIG. 17 is a diagram illustrating a generalized implementation environment in which some described examples can be implemented.

### DETAILED DESCRIPTION

### 1. Introduction

The electrical response of electrical digital interconnects, that are common on chip and at the package level in digital systems and other electronic systems, can be represented as a transfer function. A lack of causality in the transfer function is a common cause of simulation errors and inaccuracies when transfer functions or macromodels built on the transfer functions are used to simulate electrical systems.

Causality can be characterized either in the time domain or the frequency domain. In the time domain, a system can be said to be causal if the effect always follows the cause. This implies that a time domain impulse response function h(t)=0 for t<0, and a causality violation is stated if any nonzero value of h(t) is found for some t<0. To analyze causality, frequency responses can be converted to the time domain using the inverse discrete Fourier transform. This approach suffers from the Gibbs phenomenon that is inherent for functions that are not smooth enough and are represented by a truncated Fourier series. Examples of such functions include impulse response functions of typical interconnects that have jump discontinuities and whose spectrum is truncated since the frequency response data are available only on a finite length frequency interval.

Direct application of the inverse discrete Fourier transform to raw frequency response data causes severe over and under shooting near the singularities. This problem is typically addressed by windowing the Fourier data to deal with the slow decay of the Fourier spectrum. Windowing can also be applied in the Laplace domain to respect causality. There are other filtering techniques that deal with the Gibbs phenomenon, but they depend upon some knowledge of the location of singularities.

In the frequency domain, a system is said to be causal if a frequency response given by the transfer function H(ω) satisfies the dispersion relations also known as Kramers-Krönig relations. The dispersion relations can be written using the Hilbert transform. They represent the fact that the real and imaginary parts of a causal function are related through the Hilbert transform. The Hilbert transform may be expressed in both continuous and discrete forms and is widely used in circuit analysis, digital signal processing, remote sensing and image reconstruction. Dispersion relations are also used in electromagnetics and optics, particle physics, quantum mechanics, nuclear magnetic resonance, and acoustics.

The Hilbert transform that relates the real and imaginary parts of a transfer function H(ω) is defined on an infinite domain which can be reduced to [0, ∞) by symmetry properties of H(ω) for real impulse response functions. However, the frequency responses are usually available only over a finite length frequency interval, so the infinite domain is either truncated or behavior of the function for large w is approximated. This is done because measurements can only be practically conducted over a finite frequency range and often the cost of the measurements scales in an exponential manner with respect to frequency. Likewise, simulation tools have a limited bandwidth, and there is a computational cost associated with each frequency data point that generally precludes very large bandwidths in these data sets. Usually H(ω) is assumed to be square integrable, which would require the function to decay at infinity. When a function does not decay at infinity or even grows, generalized dispersion relations with subtractions can be used to reduce the dependence on high frequencies and allow a domain truncation.

In the approaches described herein, instead of approximating the behavior of H(ω) for large ω or truncating the domain, a causal periodic continuation or causal Fourier continuation of H(ω) is constructed by requiring the transfer function to be periodic and causal in an extended domain of finite length. An interconnect transfer function is approximated with a causal Fourier series in the extended domain. The approaches allow an extremely accurate approximation of an initial transfer function to be obtained on the original interval. The causality conditions are imposed exactly and directly on Fourier coefficients, so there is no need to compute Hilbert transform numerically. This eliminates the necessity of approximating the behavior of the transfer function at infinity and does not require the use of the Fast Fourier Transform.

The described approaches are capable of detecting very small localized causality violations with amplitude close to machine precision, at the order of 10⁻¹³, and a small uniform approximation error can be achieved on the entire original frequency interval, avoiding boundary artifacts that can be present when using a Hilbert MATLAB® function, polynomial continuations, or generalized dispersion relations. Error analyses described herein unbias an error due to approximation of a transfer function with a causal Fourier series from causality violations that are due to the presence of a noise or approximation errors in data. Developed estimates of upper bounds for these errors can be used in checking causality of the given data. For initial transfer functions that are determined to be non-causal, the causal, periodic continuation can be substituted for the initial transfer function to enforce causality. The causal, periodic continuation then serves as the representation of the behavior of the electrical interconnects of the system and can be used as a basis for modeling behavior of the system.

The described approaches represent a significant advance in causality assessment and enforcement with respect to transfer functions representing interconnects of electrical/electronic systems. Using the described approaches, causality violations with much smaller errors can be detected, allowing engineers correct models of integrated circuit chips, packaging, or other electronic systems prior to construction of prototypes. Construction of prototypes based on non-causal models results in prototype behavior that does not correspond to the model, which can render the prototype unusable.

Section 2, below, provides an explanation of causality for linear time-translation invariant systems and dispersion relations. In Section 3, causal spectrally accurate Fourier continuations are derived. Section 4 describes several examples. In Section 5, an error analysis is performed that takes into account possible noise or approximation errors in the given data. An approach is presented for verifying causality of given data by using the developed error estimates. Section 6 details several analytic and simulated examples, both causal and non-causal, for which causality is assessed using the described approaches to show the excellent performance of the described approaches that is consistent with the developed error estimates. Section 7 describes example implementation environments.

### 2. Causality for Linear Time-Translation Invariant Systems

Consider a linear and time-invariant physical system with the impulse response h(t, t′) subject to a time-dependent input f(t), to which it responds by an output x(t). Linearity of the system implies that the output x(t) is a linear functional of the input f(t), while time-translation invariance means that if the input is shifted by some time interval τ, the output is also shifted by the same interval, and, hence, the impulse response function h(t, t′) depends only on the difference between the arguments. Thus, the response x(t) can be written as the convolution of the input f(t) and the impulse response h(t−t′)

x(t)=∫_{-∞}^{∞}h(t−t′)f(t′)dt′=h(t)*f(t). (1)

Denote by

H(ω)=∫_{-∞}^{∞}h(τ)e^{-iωτ}dτ (2)

the Fourier transform of h(t). H(ω) is also called the transfer matrix in multidimensional case or transfer function in a scalar case.

The system is causal if the output cannot precede the input, i.e. if f(t)=0 for t<T, the same must be true for x(t). This primitive causality condition in the time domain implies h(τ)=0, τ<0, and Equation 2 becomes

H(ω)=∫₀^{∞}h(τ)e^{-ωτ}dτ. (3)

Note that the integral in Equation 3 is extended only over a half-axis, which implies that H(ω) has a regular analytic continuation in lower half ω-plane.

Examples of physical systems that satisfy the above conditions include electric networks (with f the input voltage, x the output current, H(ω) the admittance of the network; f the input current, x the output voltage, H(ω) the impedance; f, x both power waves, H(ω) the scattering), a dielectric medium, with f the applied electric field, x the dielectric polarization, and H(ω) the dielectric susceptibility of the medium among others.

For simplicity, the case with a scalar impulse response h(t) is discussed herein, but the described approaches can also be extended to the multidimensional case for any element of the impulse response matrix h(t).

It is often assumed that H(ω) is square integrable, i.e.

∫₀^{∞}|H(ω)|²dω<C (4)

for some constant C. Parseval's theorem can then be used to show that h(t) is also square integrable. The converse also holds. Square integrability of H(ω) is often related with the requirement that the total energy of the system is finite. Starting from Cauchy's theorem and using contour integration, it can be shown that for any point ω on the real axis, H(ω) can be written as

$$H ( ω ) = \frac{1}{π i} P {\int }_{–∞}^{∞} \frac{H ( {ω}^{′} )}{ω - {ω}^{′}} d {ω}^{′} , for real ω \qquad ( 5 )$$

where

$$P {\int }_{–∞}^{∞} = {lim}_{ɛ -> 0} ( {\int }_{–∞}^{ω - ɛ} + {\int }_{ω + ɛ}^{∞} ) \qquad ( 6 )$$

denotes Cauchy's principal value. Separating the real and imaginary parts of Equation 5 provides

$$\begin{matrix}Re H ( ω ) = \frac{1}{π} P {\int }_{–∞}^{∞} \frac{Im H ( {ω}^{′} )}{ω - {ω}^{′}} d {ω}^{′} and & ( 7 ) \\ Im H ( ω ) = - \frac{1}{π} P {\int }_{–∞}^{∞} \frac{Re H ( {ω}^{′} )}{ω - {ω}^{′}} d {ω}^{′} . & ( 8 )\end{matrix}$$

These expressions relating Re H and Im H are called the dispersion relations or Kramers-Krönig relations after Krönig and Kramers who derived the first known dispersion relation for a causal system of a dispersive medium. In mathematics, the dispersion relations shown in Equations 7 and 8 are also known as the Sokhotski-Plemelj formulas. These formulas show that Re H at one frequency is related to Im H for all frequencies, and vice versa. If either Re H or Im H are chosen as an arbitrary square integrable function, then the other one is completely determined by causality. Recalling that the Hilbert transform is defined

$$ℋ [ u ( ω ) ] = \frac{1}{π} P {\int }_{–∞}^{∞} \frac{u ( {ω}^{′} )}{ω - {ω}^{′}} d {ω}^{′} , \qquad ( 9 )$$

it can be that Re H and Im H are Hilbert transforms of each other, i.e.

ReH(ω)= [symbol] [ImH(ω)] and (10)

ImH(ω)=− [symbol] [ReH(ω)] (11)

For example, a function

$$H ( ω ) = \frac{1}{ω - i}$$

is clearly square integrable and satisfies the dispersion relations shown in Equations 7 and 8, which can be verified by contour integration. An example of a function H(ω) that is not square integrable but satisfies the Kramers-Krönig dispersion relations shown in Equations 7 and 8 is provided by H(ω)=e^{-iaω}, a>0. The real and imaginary parts are cos(aω) and −sin(aω), and the dispersion relations shown in Equations 7 and 8 can be verified by noting that [symbol] [cos(aω)]=sin(aω) and [symbol] [sin(aω)]=−cos(aω).

In practice, the function H(ω) may not satisfy the assumption of square integrability and it may be only bounded or even behave like O(ωⁿ), when |ω|→∞, n=0, 1, 2, . . . . In such cases, instead of the dispersion relations shown in Equations 7 and 8, generalized dispersion relations with subtractions can be used in which a square integrable function is constructed by subtracting a Taylor polynomial of H(ω) around ω=ω₀ from H(ω) and dividing the result by (ω−ω₀)ⁿ. This approach makes the integrand in the generalized dispersion relations less dependent on the high-frequency behavior of H(ω). This may be very beneficial when the high-frequency behavior of H(ω) may not be known with sufficient accuracy or not accessible in practice at all due to availability of only finite bandwidth data.

The described approaches take an alternative approach informed by the example of the periodic function H(ω)=e^{-iaω}, a>0, mentioned above, that is not square integrable but still satisfies the Kramers-Krönig dispersion relations shown in Equations 7 and 8. The transfer function H(ω) in practice is typically known only over a finite frequency interval with a limited number of discrete values and it is not periodic in general. Direct application of the dispersion relations shown in Equations 7 and 8 produces large errors in the boundary regions mainly because the high-frequency behavior of H(ω) is missing, unless data decay to zero at the boundary. To overcome this problem, the described approaches construct a spectrally accurate causal periodic continuation of H(ω) in an extended domain.

A periodic continuation, also known as Fourier continuation or Fourier extension, can be, for example, constructed based on regularized singular value decomposition (SVD) approach. This method allows calculation of Fourier series approximations of non-periodic functions such that a Fourier series is periodic in an extended domain. Causality can be imposed directly on the Fourier coefficients producing a causal Fourier continuation, thus satisfying causality exactly. The Fourier coefficients can be determined by solving an overdetermined and regularized least squares problem since the system suffers from numerical ill-conditioning. After computing the Fourier coefficients, the transfer function can be reconstructed, and the resulting causal, periodic continuation can then be compared with the given discrete measurement or simulation data on the original bandwidth of interest of an initial transfer function. A decision about causality of the given data can then be made based on how an error compares to a tolerance.

### 3. Causal, Periodic Continuations

Consider a transfer function H(ω) available at a set of discrete frequencies from [ωₘᵢₙ,ωₘₐₓ], where ωₘᵢₙ≧0. First, let ωₘᵢₙ=0, representing the baseband case. Since Equations 7 and 8 are homogeneous in the frequency variable, [0,ωₘₐₓ] can be rescaled to [0,0.5] using the transformation

$$x = \frac{0.5}{{ω}_{max}} ω$$

for convenience, to get a rescaled transfer function H(x). The time domain impulse response function h(t) is often real-valued. Hence, the real and imaginary parts of H(ω), as the Fourier transform of h(t), and, hence, of H(x), are even and odd functions, respectively. This implies that the discrete set of rescaled frequency responses H(x) is available on the unit length interval x∈[−0.5,0.5] by spectrum symmetry. In some cases, the data are available only from a non-zero, low-frequency cutoff ωₘᵢₙ>0, which corresponds to the bandpass case. The described approaches are still applicable in the bandpass case as data points are not required to be equally spaced. A transmission line example discussed in Section 6.3 considers such a situation.

An accurate Fourier series approximation of H(x) can be constructed by allowing the Fourier series to be periodic and causal in an extended domain. The result is the Fourier continuation of H, denoted by C(H), defined by

$$C ( H ) ( x ) = {\sum }_{k = M + 1}^{M} {α}_{k} {e}^{- \frac{2 π i}{b} kx} , \qquad ( 12 )$$

for even number 2M of terms, whereas for odd number 2M+1 of terms, the index k varies from −M to M. Throughout this document, Fourier series with an even number of terms are discussed for simplicity, but the described approaches are also applicable to Fourier series with an odd number of terms, and descrubed results have analogues for Fourier series with odd number of terms. Here, b is the period of approximation. For SVD-based periodic continuations b is normally chosen as twice the length of the domain on which function H is given. The value b=2 is not necessarily optimal and typically depends on a function being approximated. As used herein, “optimal,” and “optimized,” and “optimization” do not necessarily mean an absolute best but can also refer to an improvement or a best available after considering other factors.

For causal Fourier continuations the optimal value of b depends on H. Empirical observation has indicated that b can be varied from 1<b≦4 for better performance. For very smooth functions, it can be better to use a wider extension zone with b≧2. For example, b=2 or b=4 was enough in most of the examples described herein. However, for functions that are wildly oscillatory or have high gradients in the boundary regions of the domain where the original data are available, a smaller extension zone with 1<b<2 can be used. In one example described herein, b=1.1 was used. Assume that values of the function H(x) are known at N discretization or collocation points {xⱼ}, j=1, . . . , N, xⱼ∈[−0.5,0.5. Note that [symbol] (H)(x) is a trigonometric polynomial of degree at most M.

Since Re H(x) and Im H(x) are even and odd functions of A, respectively, the Fourier coefficients

$${α}_{k} = \frac{1}{b} {\int }_{- b / 2}^{b / 2} H ( x ) \overline{{φ}_{k} ( x )} d x , k = 1 , … , M , \qquad ( 13 )$$

are real. Here

$${φ}_{k} ( x ) = {e}^{- \frac{2 π i}{b} kx} ,$$

k∈Z, and - denotes the complex conjugate. Functions {φₖ(x)} form a complete orthogonal basis in

$${L}_{2} [ - \frac{b}{2} , \frac{b}{2} ] ,$$

and, in particular

∫_{-b/2}^{b/2}φₖ(x) φ̅_̅{̅k̅′̅}̅(̅x̅)̅dx=bδ_{kk′}, (14)

where δ_{kk′} is the Kronecker delta. In addition,

$$\overline{{φ}_{k}} ( x ) = {e}^{- \frac{2 π i}{b} kx} = {φ}_{- k} ( x ) .$$

For a function e^{-iax}, the Hilbert transform is

[symbol]

{e^{-iax}}=isgn(a)e^{-iax}. (15)

Hence, for functions

$${φ}_{k} ( x ) = {e}^{- \frac{2 π i}{b} kx} ,$$

[symbol]

{φₖ(x)}=isgn(k)φₖ(x), (16)

which implies that the functions {φₖ(x)} are the eigenfunctions of the Hilbert transform [symbol] with associated eigenvalues ±i with

$$x ∈ [ - \frac{b}{2} , \frac{b}{2} ] .$$

Equation 16 can be used to impose a causality condition on the coefficients of C(H)(x). In the described approaches, the square integrability of H(ω) is not required and general transfer functions can be considered.

For convenience of derivation, C(H)(x) can be written as a Fourier series

$$𝒞 ( H ) ( x ) = {\sum }_{k = - ∞}^{∞} {α}_{k} {φ}_{k} ( x ) , \qquad ( 17 )$$

which will be truncated at the end to get a Fourier continuation in the form of Equation 12. Let [symbol] (H)(x)=Re [symbol] (H)(x)+iIm [symbol] (H)(x) and φₖ(x)=Reφₖ(x)+iImφₖ(x). Since

$$Re {φ}_{k} = \frac{1}{2} ( {φ}_{k} + {\overline{φ}}_{k} ) , Im {φ}_{k} = \frac{1}{2 i} ( {φ}_{k} - {\overline{φ}}_{k} ) \qquad ( 18 )$$

it can be obtained that

$$Re 𝒞 ( H ) ( x ) = {\sum }_{k = - ∞}^{∞} {α}_{k} Re {φ}_{k} = \frac{1}{2} {\sum }_{k = - ∞}^{∞} {α}_{k} ( {φ}_{k} + {\overline{φ}}_{k} ) \qquad ( 19 )$$

and, since φ̅ₖ̅=φ₋ₖ,

$$Re 𝒞 ( H ) ( x ) = \frac{1}{2} {\sum }_{k = - ∞}^{∞} {α}_{k} ( {φ}_{k} + {φ}_{- k} ) = \frac{1}{2} {\sum }_{k = - ∞}^{∞} ( {α}_{k} + {α}_{- k} ) {φ}_{k} , \qquad ( 20 )$$

where in the last sum the order of summation in the second term has been changed. Similarly, it can be shown that

$$Im 𝒞 ( H ) ( x ) = \frac{1}{2 i} {\sum }_{k = - ∞}^{∞} ( {α}_{k} - {α}_{- k} ) {φ}_{k} . \qquad ( 21 )$$

For a causal periodic continuation, Im [symbol] (H)(x) is the Hilbert transform of −Re [symbol] (H)(x). Hence,

$$\frac{1}{2 i} {\sum }_{k = - ∞}^{∞} ( {α}_{k} - {α}_{- k} ) {φ}_{k} = - ℋ [ \frac{1}{2} {\sum }_{k = - ∞}^{∞} ( {α}_{k} + {α}_{- k} ) {φ}_{k} ] . \qquad ( 22 )$$

Employing linearity of the Hilbert transform, results in

$$\frac{1}{2 i} {\sum }_{k = - ∞}^{∞} ( {α}_{k} - {α}_{- k} ) {φ}_{k} = - \frac{1}{2} {\sum }_{k = - ∞}^{∞} ( {α}_{k} + {α}_{- k} ) ℋ [ {φ}_{k} ] . \qquad ( 23 )$$

Using Equation 16 results in

$$\begin{matrix}\frac{1}{2 i} ( {α}_{k} - {α}_{- k} ) = - \frac{1}{2} ( {α}_{k} + {α}_{- k} ) i sgn ( k ) for any k ∈ Z or & ( 24 ) \\ {α}_{k} - {α}_{- k} = ( {α}_{k} + {α}_{- k} ) sgn ( k ) , k ∈ Z , & ( 25 )\end{matrix}$$

that implies αₖ=0 for k≦0. Hence, a causal Fourier continuation can then be written

$$𝒞 ( H ) ( x ) = {\sum }_{k = 1}^{M} {α}_{k} {φ}_{k} ( x ) \qquad ( 26 )$$

where the infinite sum is truncated to obtain a trigonometric polynomial. Evaluating H(x) at points xᵢ, j=1, . . . , N, x₃∈[−0.5,0.5, produces a complex valued system

$$𝒞 ( H ) ( {x}_{j} ) = {\sum }_{k = 1}^{M} {α}_{k} {φ}_{k} ( {x}_{j} ) \qquad ( 27 )$$

with N equations for M unknowns αₖ, k=1, . . . , M, N≧M. If N>M, the system shown in Equation 27 is overdetermined and is solved in the least squares sense. When Fourier coefficients αₖ are computed, Equation 26 provides reconstruction of H(x) on [−0.5,0.5].

To ensure that numerically computed Fourier coefficients αₖ are real, instead of solving the complex-valued system of Equation 27, the real and imaginary parts of C(H)(xⱼ) can be separated to obtain real-valued system

$$Re 𝒞 ( H ) ( {x}_{j} ) = {\sum }_{k = 1}^{M} {α}_{k} Re {φ}_{k} ( {x}_{j} ) , \\ Im 𝒞 ( H ) ( {x}_{j} ) = {\sum }_{k = 1}^{M} {α}_{k} Im {φ}_{k} ( {x}_{j} ) . \qquad ( 28 )$$

This produces 2N equations (N equations for both real and imaginary parts) and M unknowns αₖ. As demonstrated below, both the complex (Equation 27) and real (Equation 26) formulations give the reconstruction errors of the same order with the real formulation performing slightly better. To distinguish between the continuation [symbol] (H) computed using complex or real formulation, the notation [symbol] ^{C}(H) and [symbol] ^{R}(H), respectively, will be used.

Considering the real formulation shown in Equation 28, the following notation is introduced. Let \vec{ƒ}=(Re H(x₁), . . . , Re H (x_{N}), Im H(xᵢ), . . . , Im H(x_{N}))^{T}, \vec{α}=(α₁, . . . , α_{M})^{T}, where ^{T} denotes the transpose, and matrix A have entries

$$\begin{matrix}{A}_{jk} = Re \{ {e}^{- \frac{2 π i}{b} {kx}_{j}} \} , j = 1 , … , N , k = 1 , … , M , & ( 29 ) \\ {A}_{( j + N ) , k} = Im \{ {e}^{- \frac{2 π i}{b} {kx}_{j}} \} , j = 1 , … , N , k = 1 , … , M . & ( 30 )\end{matrix}$$

Similar notation can be made for the complex formulation in Equation 27. Then the coefficients αₖ, k=1, . . . , M, are defined as a least squares solution of A\vec{α}=\vec{ƒ} written as

$${min}_{\{ {α}_{k} \}} {\sum }_{j = 1}^{2 N} {\vert {\sum }_{k = 1}^{M} {α}_{k} {A}_{jk} - {f}_{j} \vert}^{2} , \qquad ( 31 )$$

that minimizes the Euclidean norm of the residual. This least squares problem is extremely ill-conditioned. However, it can be regularized using a truncated SVD method when singular values below some cutoff tolerance ξ close to the machine precision are being discarded. In this document, ξ=10⁻¹³ is used as the threshold to filter the singular values. The ill-conditioning increases as M increases by developing rapid oscillations in the extended region. These oscillations are typical for SVD-based Fourier continuations. Once the system reaches a size that does not depend on the function being approximated, the coefficient matrix becomes rank deficient and the regularization of the SVD is used to treat singular values close to the machine precision. Because of the rank deficiency, the Fourier continuation is no longer unique. Applying the truncated SVD method produces the minimum norm solution {αₖ}, k=1, . . . , M, for which the corresponding Fourier continuation is oscillatory. The oscillations in the extended region do not significantly affect the quality of the causal Fourier continuation on the original domain and varying b can minimize their effect and decrease the overall reconstruction error, especially in the boundary domain.

Another way to make ill-conditioning of matrix problems shown in Equation 26 and Equation 27 better is to use more data (collocation) points N than the Fourier coefficients M. This is called “overcollocation” and makes the problem more overdetermined and helps to increase the accuracy of solutions. In some examples, at least twice as many collocation points N are used than the Fourier coefficients M, i.e. N=2M. The convergence can be checked by keeping the number of Fourier coefficients M fixed and increasing the number of collocation points N. The overcollocation also helps with filtering out trigonometric interpolants that have very small errors at collocation points xⱼ but large oscillations between the collocation points. In examples detailed below in Section 6 at least N=2M is used as an effective way to obtain an accurate and reliable approximation of H(x) over the interval [−0.5,0.5].

In the multidimensional case when a transfer matrix H(ω) is given, the above procedure can be extended to all elements of the matrix. Computing SVD is an expensive numerical procedure for large matrices. The operation count to find a least squares solution of Ax=b using the SVD method with A being N×M, N≧M, matrix, is of the order O(NM²+M³). The actual CPU times for computing SVD, solving a linear system in the least squares sense, and constructing causal Fourier continuations for various values of M used in the examples detailed herein, are shown in Table 3 in Section 6. Computational savings can be achieved by noting that in the described approaches, the matrix A depends only on the location of frequency points at which the transfer matrix is evaluated/available, and continuation parameters M and b, but does not depend on actual values of H(ω). Having frequency responses at N points, N=2M can be fixed, b=2 can be chosen as a default value, SVD can be computed only once prior to verifying causality. Varying 1<b≦4 or 2M<N for each element of H(ω) separately, if needed, would require recomputing SVD.

### 4. Examples of the Described Approaches

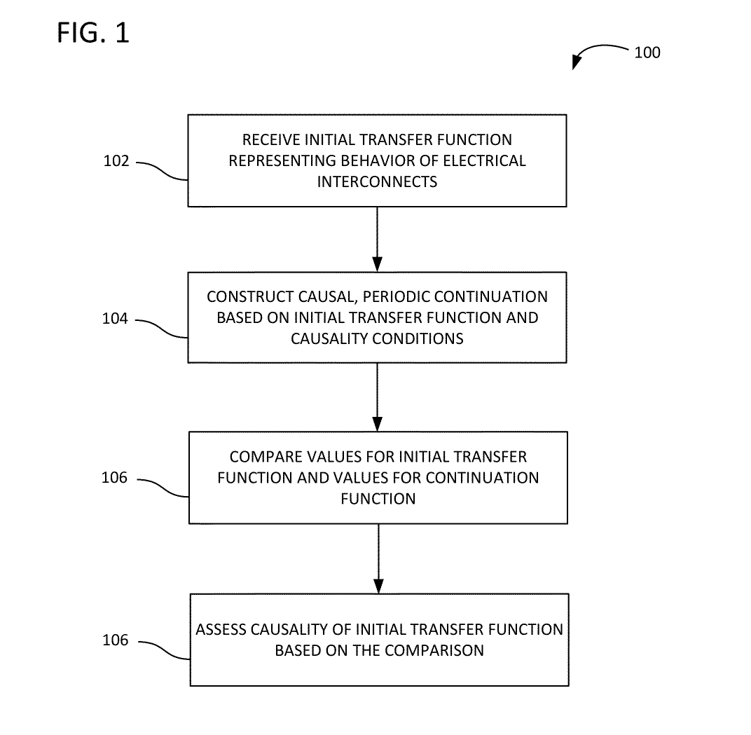

FIG. 1 illustrates a method 100 for evaluating causality. In process block 102, an initial transfer function representing the behavior of electrical interconnects of a system over an initial frequency range (i.e., the initial transfer function is “band limited”) is received. The initial transfer function can be based on at least one of simulation results for the system or measurements of the system. The initial transfer function can represent, for example, admittance parameters of the system, impedance parameters of the system, or scattering parameters of the system. The system can be an electronic system. In some examples, the system comprises at least one of an integrated circuit or packaging of an integrated circuit.

In process block 104, a causal, periodic continuation is constructed based on the initial transfer function and one or more causality conditions. The continuation is periodic over an extended frequency range that is larger than the initial frequency range. Detailed examples of construction of a causal, periodic continuation are discussed above in Section 3. The one or more causality conditions can include dispersion relations represented through a Hilbert transform, as discussed in Sections 2 and 3. An example causality condition is that the imaginary part of the continuation is a Hilbert transform of a negative of a real part of the continuation. Constructing the causal, periodic continuation in process block 104 can include (i) approximating the initial transfer function as a Fourier series and (ii) determining values for Fourier coefficients of the Fourier series such that the one or more causality conditions are satisfied. In determining the values for the Fourier coefficients, it can also be required that values for the continuation match values of the initial transfer function for a plurality of frequencies. Determining the values for the Fourier coefficients can be accomplished in part by applying a truncated singular value decomposition (SVD) approach to control ill-conditioning.

In process block 106, values for the initial transfer function and values for the continuation are compared at a plurality of frequencies. The causality of the initial transfer function is assessed in process block 108 based on the comparing. Assessing causality can include, upon determining that an error based on the comparing is below a threshold, determining that the initial transfer function representing the behavior of the electrical interconnects of the system is causal. The threshold can be selected based on at least one of smoothness of the initial transfer function, a number of Fourier coefficients in the continuation, or noise in data on which the initial transfer function is based. The error can be determined as at least one of (i) a first error that is the difference between a real part of the initial transfer function and a real part of the continuation or (ii) a second error that is the difference between an imaginary part of the initial transfer function and an imaginary part of the continuation.

Assessing causality can also include, upon determining that an error based on the comparing is above a threshold, determining that at least one of: (i) the initial transfer function representing the behavior of the electrical interconnects is non-causal or (ii) a number of values for the initial transfer function at different frequencies has resulted in error from discretization being above the threshold. Error is discussed in greater detail below in Section 5.

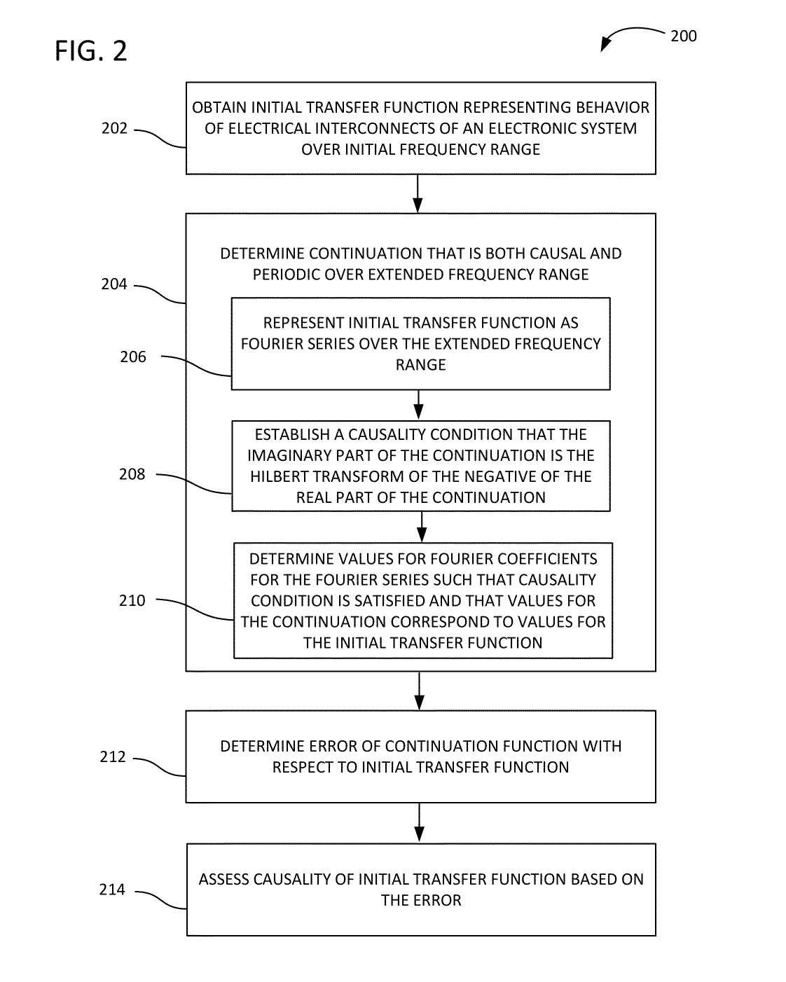

FIG. 2 illustrates another method 200 for evaluating causality. In process block 202, an initial transfer function is obtained. The initial transfer function represents the behavior of electrical interconnects of an electronic system over an initial frequency range. In process block 204, a continuation is determined that is both causal and periodic over an extended frequency range. The continuation is determined through at least process blocks 206, 208, and 210. In process block 206, the initial transfer function is represented as a Fourier series over the extended frequency range. In process block 208, a causality condition is established in the frequency domain. The causality condition can specify, for example, that an imaginary part of the continuation is a Hilbert transform of a negative of a real part of the continuation. In process block 210, values for Fourier coefficients for the Fourier series are determined such that (i) the causality condition is satisfied and (ii) for a plurality of frequencies within the initial frequency range, values of the continuation correspond to values for the initial transfer function.

An error of the continuation with respect to the initial transfer function is determined in process block 212. The causality of the initial transfer function is assessed in process block 214 based on the error. Assessing the error can comprise comparing the error to a threshold. When the error is below the threshold, the initial transfer function is causal. When the error is above the threshold, the initial transfer function is either non-causal, or a number of values obtained for the initial transfer function at different frequencies has resulted in the error being a discretization error above the threshold.

In another example, the causality of an initial transfer function H(ω) given at discrete points over the frequency range [ωₘᵢₙ, ωₘₐₓ] is evaluated. The accuracy of the samples of H(ω), which are obtained from either experiments or numerical simulation, is represented by ∈. Values of H(ω) can be reflected over [−ωₘₐₓ, ωₘᵢₙ] using spectrum symmetry. That is Re H and Im H are even and odd functions, respectively. The frequency interval can be resealed to [−0.5, 0.5] by substitution using x=(0.5/ωₘₐₓ) ω if ωₘᵢₙ=0 to get a function H(x). If ωₘᵢₙ>0, the resealed interval is [−0.5, −a]∪[a, 0.5], with a=0.5(ωₘᵢₙ/ωₘₐₓ). Let H(x) have N values at points x₁, x₂, . . . x_{N}∈|−0.5, 0.5]. The approach with ωₘᵢₙ>0 is similar. Fix M=N, where M/2 is the number of Fourier coefficients used to define a causal Fourier continuation. Next, b=2 is chosen as the default length of the extended domain.

Either the complex or real formulations can be solved in the least squares sense to find Fourier coefficients aₖ, k=1, . . . , M/2. Once coefficients {aₖ} are computed, Re H and Im H can be reconstructed. Reconstruction errors E_{R}(x) and E_{I}(x), x∈[−0.5, 0.5] can then be calculated. The l_{∞} norm, for example, can be used to compare the errors with the given tolerance ∈. If ∥E_{R}∥_{∞}<∈ and ∥E_{I}∥_{∞}<∈, then the function H(x), and, hence H(ω), are causal with the error not exceeding ∈. Other norms such as the l₂ norm can also be used.

To verify if a smaller reconstruction error can be obtained, the length b can be varied. For smooth functions, a larger value of 2<b<4 or 2<b<6 can be used to try decreasing overall error. For functions that have high frequency oscillations and steep slopes in the boundary regions, a smaller value 1<b<2 may give better results. If ∥E_{R}∥_{∞}≧∈ or ∥E_{I}∥_{∞}≧∈, then the function H(x), and, hence H(ω), is not causal. Typically, the reconstruction errors E_{R}(x) and E_{I}(x) are of the same order. For non-causal systems, increasing N results in the increase of E_{R}(x) and E_{I}(x) and varying b does not affect these errors substantially. A detailed error discussion is presented below in Section 5.

### 5. Error Analysis

In this section, an upper bound is provided for the error in approximation of a given function H(x) by its causal Fourier continuation [symbol] (H)(x). The obtained error estimates can be employed to characterize causality of an initial transfer function representing a given set of data.

### 5.1 Error Estimates

Denote by Ĥ_{M} any function of the form

$${\hat{H}}_{M} ( x ) = {\sum }_{k = 1}^{M} {\hat{α}}_{k} {φ}_{k} ( x ) \qquad ( 32 )$$

where

$${φ}_{k} ( x ) = {e}^{- \frac{2 π i}{b} kx} ,$$

k=1, . . . , M, as before. Let A=UΣV* be the full SVD decomposition of the matrix A with entries Aₖⱼ=φₖ(xⱼ), j=1, . . . , N, k=1, . . . , M, where U is an N×N unitary matrix, Σ is an N×M diagonal matrix of singular values σⱼ, j=1, . . . , p, p=min (N, M), V is an M×M unitary matrix with entries Vₖⱼ, and V* denotes the complex conjugate transpose of V. The following result can then be proved.

Theorem 1—

Consider a rescaled transfer function H(x) defined by symmetry on Ω=[−0.5, −a]∪[a,0.5], where

$$a = 0.5 \frac{{ω}_{min}}{{ω}_{max}} ,$$

whose values are available at points xⱼ∈Ω, j=1, . . . , N. Then the error in approximation of H(x), that is known with some error ∈, by its causal Fourier continuation [symbol] (H)(x) defined in Equation 26 on a wider domain Ω^{c}=[b/2,b/2], b≧1, has the upper bound

∥H− [symbol] (H+∈)∥_{L}_{₂}_{(Ω)}≦(1+Λ₂{square root over (N(M−K)))}×(∥H−Ĥ_{M}∥_{L}_{_{∞}}_{(Ω)}+∥∈∥_{L}_{_{∞}}_{(Ω)})+Λ₁\sqrt{K/b}∥Ĥ_{M}∥_{L}_{_{∞}}_{(Ω}_{^{c}}₎ (33)

and holds for all functions of the form of Equation 32. Here,

$${Λ}_{1} = {max}_{j : {σ}_{j} < ξ} {‖ {v}_{j} ( x ) ‖}_{{L}_{2} ( Ω )} , {Λ}_{2} = {max}_{j : {σ}_{j} > ξ} \frac{{‖ {v}_{j} ( x ) ‖}_{{L}_{2} ( Ω )}}{{σ}_{j}} , \qquad ( 34 )$$

and functions vⱼ(x)=Σₖ₌₁^{M}Vₖⱼφₖ(x) are each an up to M term causal Fourier series with coefficients given by the jth column of V; K denotes the number of singular values that are discarded, i.e. the number of j for which σⱼ<ξ, where ξ is the cut-off tolerance.

Proof—

To obtain the error bound in Equation 33 we employ a complex formulation and impose causality on Fourier coefficients. The error bound for ∥H− [symbol] (H)∥_{L}_{₂}_{(Ω)} is expressed in terms of the error ∥H−Ĥ_{M}∥_{L}_{_{∞}}_{(Ω)} in approximation of a function with a causal Fourier series and ∥Ĥ_{M}∥_{L}_{_{∞}}_{(Ω}_{^{c}}₎ for any given causal Fourier series Ĥ_{M}. This involves finding upper bounds for ∥ [symbol] (H−Ĥ_{M})∥_{L}_{₂}_{(Ω)} and ∥Ĥ_{M}− [symbol] (Ĥ_{M})∥_{L}_{₂}_{(Ω)} that estimate the error due to truncation of singular values and the effect of Fourier continuation on the error in approximation of a function with a causal Fourier series. If function H is known with some error ∈, its effect is also included in a straight-forward way. The bound for ∥H−Ĥ_{M}∥_{L}_{_{∞}}_{(Ω)} follows from Jackson's Theorems that estimate the error in approximation of a periodic function with its M causal Fourier series Ĥ_{M} as a partial case. Indeed, a causal M mode Fourier series can be considered as an 2M mode Fourier series whose coefficients with nonpositive indices are zero. Hence, the error in approximating a b-periodic function H with k continuous derivatives with a causal M mode Fourier series, has the following upper bound:

$${‖ H - {\hat{H}}_{M} ‖}_{{L}_{∞} ( Ω )} \leq \frac{π}{2} {( \frac{b}{π} )}^{k} {( \frac{1}{2 M} )}^{k} {‖ {H}^{( k )} ‖}_{{L}_{∞} ( {Ω}^{c} )} . \qquad ( 35 )$$

Left and right singular vectors that form columns of matrices U and V are used in the derivation of the error estimates shown in Equations 33 and 34 as alternatives to Fourier basis.

As can be seen from Equation 34, Λ₁, Λ₂ and K depend only on the continuation parameters N, M, b and ξ as well as location of discrete points xⱼ, and not on the function H. The behavior of Λ₁\sqrt{K/b} and Λ₂\sqrt{N(M−K)} as functions of M can be investigated using direct numerical calculations. This is done here for the case of equally spaced points xⱼ, j=1, . . . , N, which is typical in applications, and N=2M with b=2 is used. Other distributions of points xⱼ, values of b and relations between M and N can be analyzed in a similar manner. For example, results for b=4 are very similar to the case with b=2.

While Λₗ does not change much with M and remains small, the coefficient Λ₁\sqrt{K/b} stays close to the cut-off value ξ for small M and increases at most to 10ξ for large M. This behavior does not seem to depend on the cut-off value ξ and the results are similar for ξ varying from 10⁻¹³ to 10⁻⁷. The number K of discarded singular values grows with M (provided that singular values above ξ are computed accurately) since the ill-conditioning of the problem increases with M. Values of Λ₂ remain close to 1 for values M we considered. At the same time, the coefficient Λ₂\sqrt{N(M−K)} grows approximately as \sqrt{M} as M increases.

Since the error shown in Equation 35 in approximation of a function with a causal Fourier series decays as [symbol] (M^{-k}) and the coefficient Λ₂\sqrt{N(M−K)} grows as [symbol] (M), the error bound part that is due to a causal Fourier series approximation

∈_{F}≡(1+Λ₂\sqrt{N(M−K)})∥H−Ĥ_{M}∥_{L}_{_{∞}}_{(Ω)} (36)

decays at least as fast as [symbol] (M^{-k+1}). A causal Fourier series converges slightly slower than a standard Fourier series.

In practice, the smoothness order k of the transfer function H(x) may not be known. In this case, it can be estimated by noting that the error bound ∈_{F} can be written as

∈_{F}˜\tilde{C}M^{-k+1}. (37)

Taking the natural logarithm of both sides provides

ln ∈_{F}˜ln \tilde{C}+(−k+1)ln M, (38)

i.e. ln ∈_{F} is approximately a linear function of ln M. The values of \tilde{C} and k can be estimated as follows. Assume that H is known at N frequency points. Usually the number of frequency responses is fixed, and it may not be possible to get data with higher resolution. Assume that the errors due to truncation of singular values (term with Λ₁) and a noise in data (term with ∥∈∥_{L}_{_{∞}}_{(Ω)}) are small, so that the error due to a causal Fourier series approximation is dominant. Let E_{R}(x) and E_{I}(x) be reconstruction errors,

E_{R}(x)=ReH(x)−Re [symbol] (H)(x), (39)

E_{I}(x)=ImH(x)−Im [symbol] (H)(x) (40)

on the original interval [−0.5,0.5]. The resconstruction errors E_{R}(x) and E_{I}(x) can be computed with N, N/2, N/4 etc. samples, i.e. with M, M/2, M/4 etc. Fourier coefficients. Equation 38 can be solved in the least squares sense to find approximations of ln \tilde{C} and −k+1, and, hence, to \tilde{C} and k. Then the error term ∈_{F} can be extrapolated to higher values of M using Equation 37 to see if the causal Fourier series approximation error decreases if the number M of Fourier coefficients increases, i.e. resolution increases.

The error bound term

∈_{T}=Λ₁\sqrt{K/b}∥Ĥ_{M}∥_{L}_{_{∞}}_{(Ω}_{^{c}}₎, (41)

that is due to the truncation of singular values is typically small and close to the cut-off value ξ for small M<250 and at most 10ξ for 250≦M≦1500. As can be seen from Equation 41, ∈_{T} depends on b and the function H being approximated. The default value b=2 may not provide the smallest error. To find a more optimal value of b, a few values in 1<b≦4 can be tried to determine if one gives a smaller overall reconstruction errors. For non-causal functions, varying b does not essentially affect the size of reconstruction errors.

The error ∈ in data should be known in practice since the error in measurements or the accuracy of full wave simulations are typically known. The error bound term due to a noise in the data

∈ₙ=(1+Λ₂\sqrt{N(M−K)})∥∈∥_{L}_{_{∞}}_{(Ω)} (42)

consists of the norm of the noise amplified by the coefficient Λ₂\sqrt{N(M−K)}) that grows as [symbol] (M) as was shown above. In conducted numerical experiments, the reconstruction errors due to noise in the data seem to level off to the order of ∈ and are not amplified significantly as the resolution increases. This does not contradict the error estimate shown in Equations 33 and 34. The error bounds are not tight and the actual reconstruction errors may be smaller than the error bounds suggest.

### 5.2 Causality Characterization

The error estimate in Equations 33 and 34 shows that the reconstruction errors E_{R}(x) and E_{I}(x) defined in Equations 39 and 40 can be dominated by either the error due to approximation of a function with its causal Fourier series, which has the upper bound ∈_{F}, or the error ∈ due to a noise or approximation errors in data, which has the upper bound ∈ₙ. If the only errors in data are round-off errors, then the reconstruction errors will approach or will be bounded by the error due to truncation of singular values, which has the upper bound ∈_{T}. The noise level ∈ may be known. In the case of experimental data, ∈ could be around 10⁻³ or 10⁻⁴, for example. Data obtained from finite element simulations may be accurate within 10⁻⁶ or 10⁻⁷, for instance, which would correspond to a single precision accuracy. In some cases, the expected accuracy may be even higher. In this case if the reconstruction errors are higher than ∈ₙ (in practice ∈ can be used), then the reconstruction errors may be dominated by a causal Fourier series approximation error with the upper bound ∈_{F}.

Determining the smoothness order of H using the model of Equation 37 with N, N/2, N/4 etc. samples can give an answer whether the causal Fourier series approximation error can be made smaller by increasing the resolution of the data. If the model of Equation 37 is extrapolated to higher values of M and decays with M, this implies that the Fourier series approximation error can be decreased by using more frequency samples. Then it can be stated that the dispersion relations are satisfied within error given by E_{R}(x) and E_{I}(x), and causality violations, if present, have the order smaller than or at most the order of reconstruction errors E_{R}(x) and E_{I}(x).

In this case, with fixed resolution, the described approaches may not detect these smaller causality violations. The noise level ∈ may not be known but it can be determined by comparing reconstruction errors E_{R}(x) and E_{I}(x) as the resolution of data increases, if possible, or decreases, since the reconstruction error due to the noise does not significantly depend on the resolution in practice. This means that as the number N of samples increases, the reconstruction errors level off at the value of the noise ∈. Equivalently, there may be a situation that by using N, N/2, N/4 etc. samples (resolution becomes coarser), the reconstruction error does not increase. Instead, it remains at the same order, which would be a noise level ∈. In this case, the dispersion relations will be satisfied within the error ∈, which would be the order of causality violations. A similar situation is discussed below with respect to a finite element model of a package in Example 6.2 of Section 6.

### 6. Detailed Examples

In this section, described approaches of constructing causal, periodic continuations are used in several analytic and simulated examples that are causal/non-causal or have imposed causality violations. When a given transfer function H(x) is causal, the dispersion relations shown in Equations 7 and 8 are satisfied with the accuracy close to machine precision. This is called an “ideal causality test.” When there is a causality violation, the described approaches are able to point to the location of violation or at least develop reconstruction error close to the order given by the noise in data as suggested by the error analysis. Results for the below examples are in full agreement with the error estimates developed in Section 5.

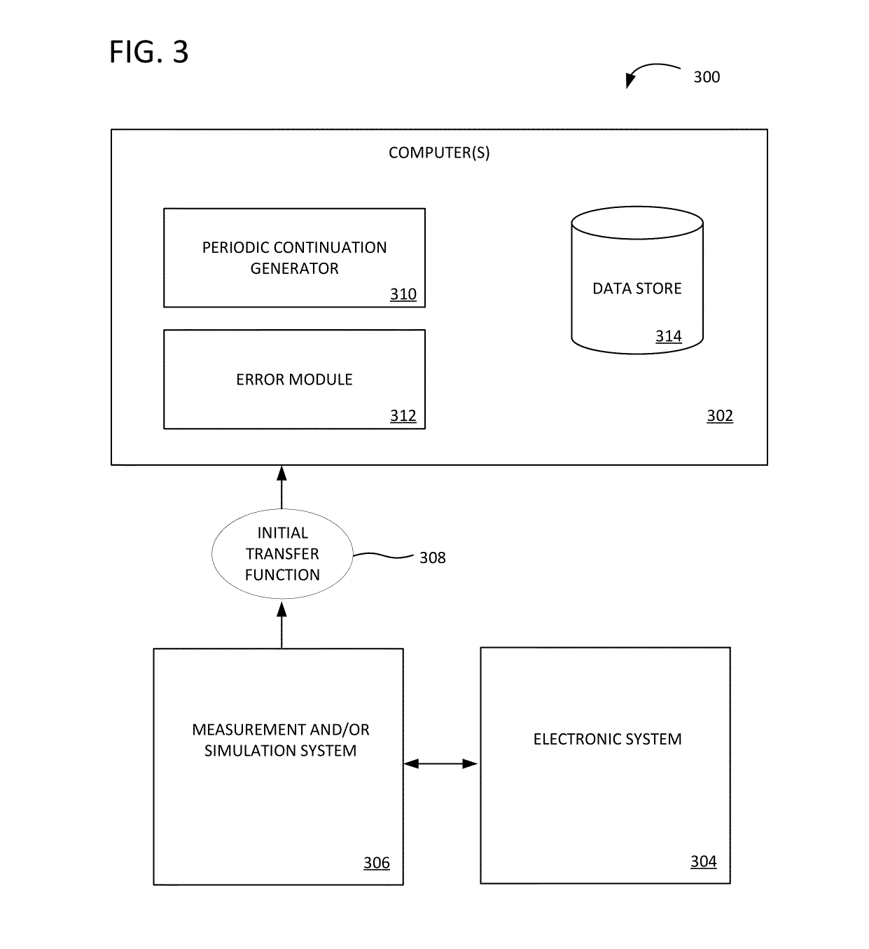

FIG. 3 illustrates an example system 300 capable of evaluating causality. A system such as system 300 can be used to assess causality in the examples below. System 300 is implemented on one or more computers 302. Computers 302 can be various types of computing device(s), including server computers, client computers, or mobile devices. Measurements and/or simulation results for an electronic system 304 are obtained through measurement and/or simulation system 306. Measurement and/or simulation system 306 can include various hardware measurement devices, computers, simulation hardware and/or software, etc. Measurement and/or simulation system 306 produces an initial transfer function 308 representing the behavior of electrical interconnects of electronic system 304 over an initial frequency range. Initial transfer function 308 can represent at least one of simulation results for or measurements of admittance, impedance, or scattering parameters for the electrical interconnects in electronic system 304. Initial transfer function 308 is provided to system 300. Electronic system 304 can be or include, for example, an integrated circuit or packaging for an integrated circuit.

Periodic continuation generator 310 is configured to: based on (i) initial transfer function 308 and (ii) one or more causality conditions, determine a causal, periodic continuation over an extended frequency range that is larger than the initial frequency range. Periodic continuation generator 310 can be configured to determine the causal, periodic continuation by approximating initial transfer function 308 as a Fourier series over the extended frequency range and determining values for Fourier coefficients of the Fourier series. Periodic continuation generator 310 can also be configured to determine values for the Fourier coefficients by: imposing the one or more causality conditions in the frequency domain and determining the values for the Fourier coefficients through a least squares approach such that (i) the one or more causality conditions are satisfied and (ii) for a plurality of frequencies within the initial frequency range, values of initial transfer function 308 correspond to values for the continuation.

Error module 312 is configured to assess causality of initial transfer function 308 by determining an error of the continuation with respect to initial transfer function 308. Error module 312 can also be configured to assess causality by comparing the error to a threshold, wherein when the error is below the threshold, error module 312 determines that initial transfer function 308 is causal, and wherein when the error is above the threshold, error module 312 determines that at least one of: (i) initial transfer function 308 is non-causal or (ii) a resolution of data upon which the initial transfer function is based is low enough to result in error being above the threshold.

Data store 314 stores initial transfer function 308, and can store other data, intermediate calculations, parameters, etc. used in determination of the continuation by periodic continuation generator 310.

### 6.1 Two-Pole Example

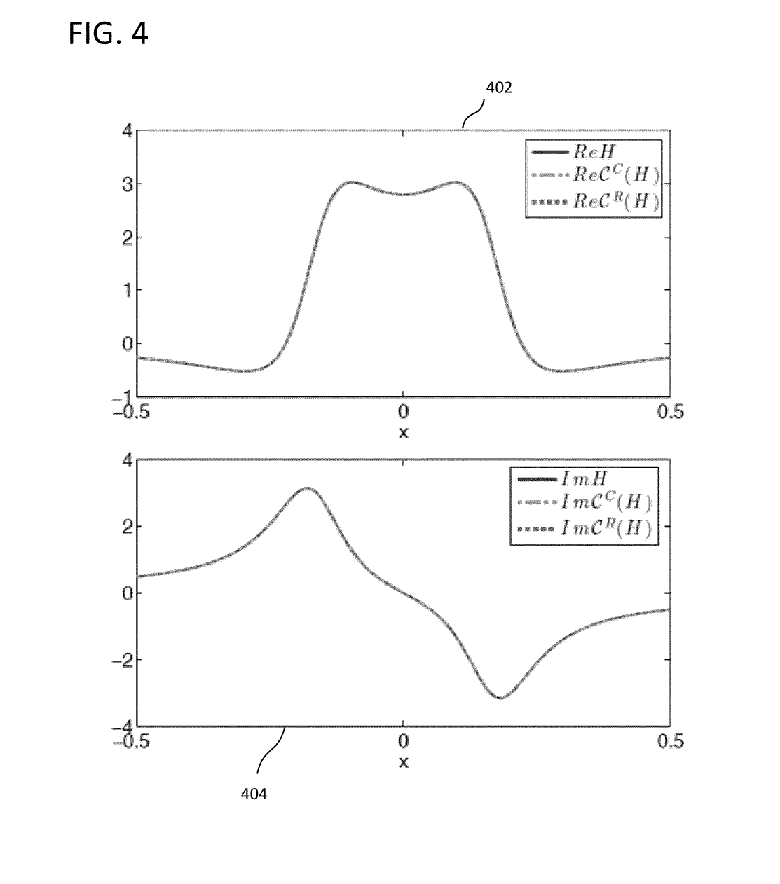

A two-pole transfer function with no delay is defined by

$$H ( ω ) = \frac{r}{i ω + s} + \frac{\overline{r}}{i ω + \overline{s}} \qquad ( 43 )$$

where r=1+3i, s=1+2i. Since both poles of this function located at ±2+i are in the upper half plane, the transfer function is causal as a linear combination of causal transforms. Data is sampled on the interval from ω=0 to ωₘₐₓ=6, using spectrum symmetry to obtain data on [−ωₘₐₓ,0) and scale the frequency interval from [−ωₘₐₓ, ωₘₐₓ] to [−0.5,0.5]. FIG. 4 shows plots 402 and 404 of the real and imaginary parts of H(x). Superimposed on plots 402 and 404 are the corresponding causal Fourier continuations, [symbol] ^{C}(H) and [symbol] ^{R}(H), complex and real, obtained using M=250, N=1000, b=4 by solving the complex system shown in Equation 27 and its real counterpart shown in Equation 28. As can be seen, there is essentially no difference in using the complex or real formulation, though the real formulation shown in Equation 28 is slightly more ill-conditioned than the complex one. The data and the causal Fourier continuations are practically indistinguishable on [−0.5,0.5].

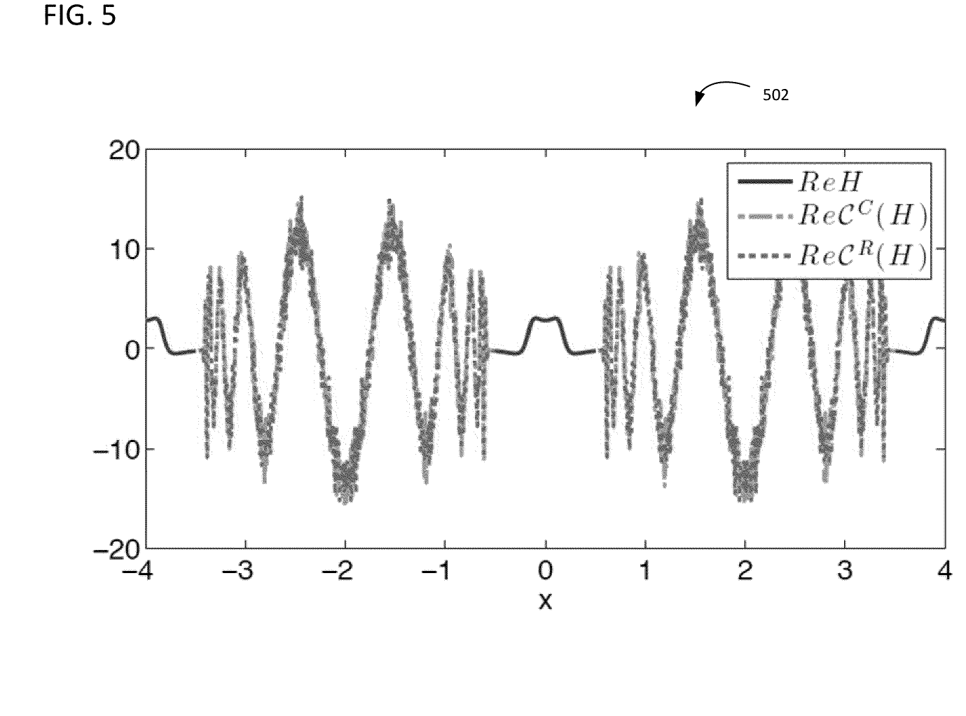

The nature of continuations is demonstrated in plot 502 of FIG. 5. Plot 502 includes the same curves as in plot 402 of FIG. 4 (only the real parts are presented, the imaginary parts have similar features) but on the extended domain [−4,4] where two periods are shown. It is clear that the continuations oscillate in the extended region outside [−0.5,0.5]. The frequency of these oscillations increases with M. At the same time, the Fourier series becomes more and more accurate an approximation over the original interval [−0.5,0.5].

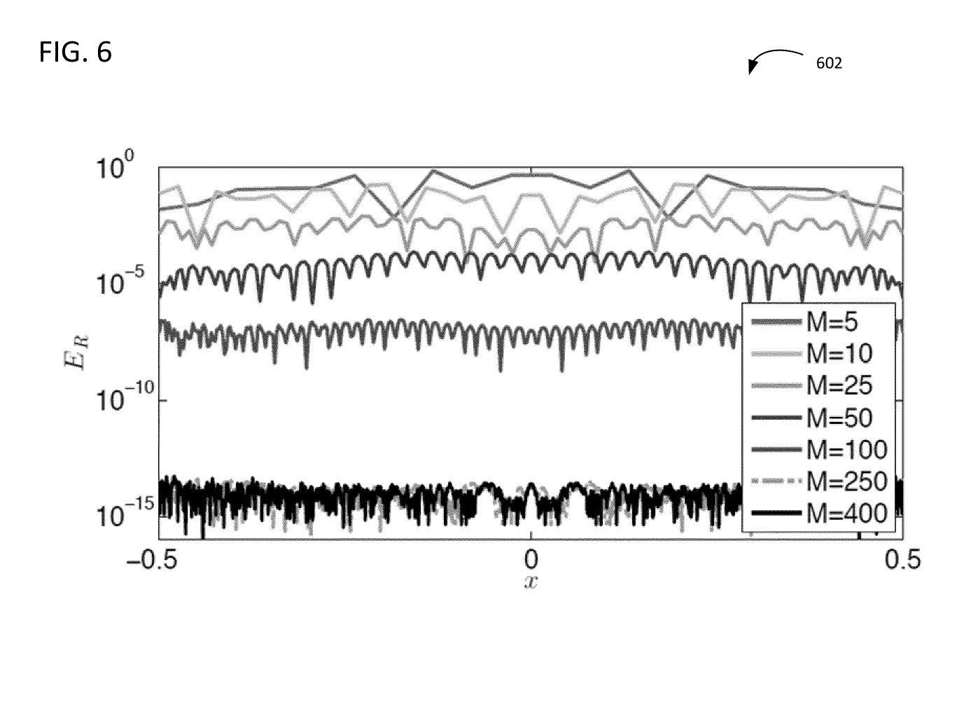

To demonstrate this, the reconstruction errors E_{R}(x), defined in Equations 39 and 40 are shown in plot 602 of FIG. 6 (plot 602 is a plot using the MATLAB® semilogy function, hereinafter “semilogy plot”) in [−0.5,0.5] for various values of M with N=4M obtained using the real formulation shown in Equation 28. The results for E_{I}(x) are similar. As M increases from M=5 to 250, the order of the error decreases from 10⁻¹ to 10⁻¹⁴ for both real and imaginary parts. For example, with M=250, N=1000, b=4, both errors E_{R}(x) and E_{I}(x) are at the order of 4×10⁻¹⁴. The results indicate that the error is uniform on the entire interval [−0.5,0.5] and does not exhibit boundary artifacts.

These results demonstrate that the described approaches capable of verifying that the given data are causal with high accuracy. In this case, causality is satisfied with the error less than 10⁻¹³. These results are in agreement with the error estimates developed in Section 4. Since the data do not have any noise except for rounding errors and the transfer function is smooth on [−0.5,0,5], the reconstruction errors are dominated by the fast decaying error in approximation of the smooth transfer function with its causal Fourier series for smaller M and then by the error due to truncation of the singular values for high values of M, which is close to the cut-off value ξ=10⁻¹³. Another observation can be made about the behavior of the errors E_{R}(x) and E_{I}(x) as M increases for a causal smooth function. Even for small values of M, as M doubles, the errors decrease by several orders of magnitude until the errors level off around 5×10⁻¹⁴ (see Table 1, below). This is a consequence of the fast convergence of a Fourier series for a smooth function.

TABLE 1

| N | M | \|\| E_{R} \|\|_{∞}, \|\| E_{I} \|\|_{∞} | Al | M | \|\| E_{R} \|\|_{∞}, \|\| E_{I} \|\|_{∞} |
|---|---|---|---|---|---|
| 40 | 10 | ~10⁻¹ | 400 | 100 | ~10⁻⁷ |
| 100 | 25 | ~4 × 10⁻³ | 800 | 200 | ~2 × 10⁻¹³ |
| 200 | 50 | ~10⁻⁴ | 1000 | 250 | ~5 × 10⁻¹⁴ |

Table 1 illustrates the orders of errors E_{R}(x) and E_{I}(x) in example 6.1 to demonstrate how fast reconstruction errors decay as resolution increases in the case of a causal smooth function.

Next, the sensitivity of the described approaches to causality violations is tested. This is done by imposing a localized non-causal perturbation on causal data. This artificial causality violation is modeled by a Gaussian function

$$a exp ( - \frac{{( x - {x}_{0} )}^{2}}{2 {σ}^{2}} ) \qquad ( 44 )$$

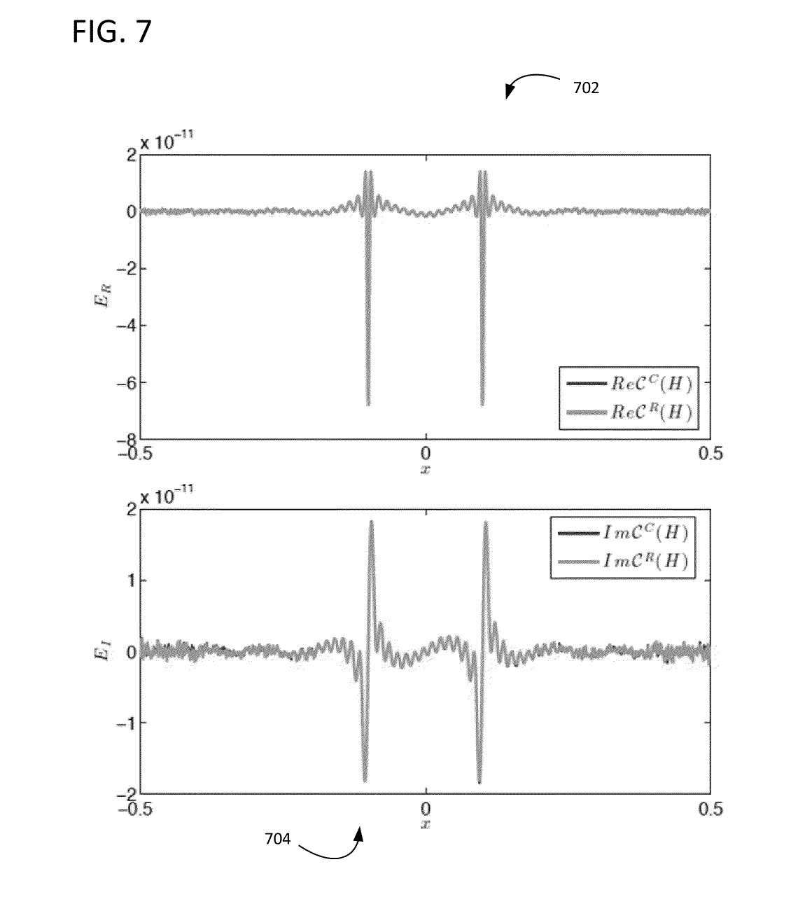

of small amplitude a, centered at xₒ and added to Re H, while keeping Im H unchanged. A Gaussian centered at x₀=0.1 with standard deviation σ=10⁻²/6 is used, so its “support” is concentrated on a very narrow interval of length 10⁻² and outside this interval the values of the perturbation are very close to 0. An advantage of using a Gaussian perturbation is that it can be localized and allows verification of whether the described approaches are capable of detecting the location of causality violation. By varying the amplitude a, larger or smaller causality violations can be imposed. The smaller the a that can be used, the more sensitive the described approaches are for detecting causality violations. With a=10⁻¹⁰, which gives a very small causality violation, the error between the data and its causal Fourier continuation is shown in plots 702 and 704 of FIG. 7. Plots 702 and 704 are semilogy plots of E_{R}(x) and E_{I}(x) for example 6.1 with Gaussian perturbation with a=10⁻¹° on [−0.5,0.5] with M=250, N=1000, b=4.

It is clear that the error has very pronounced spikes at x=±0.1 due to symmetry that corresponds to the exact locations of the Gaussian perturbation. These spikes are of the order 10⁻¹¹ whereas on the rest of the interval the error is about 10 times smaller. For larger perturbations, the results are similar. For example, with a=10⁻⁸, the error at ±0.1 is of the order of 10⁻⁹ and the rest of the interval has the error 10 times smaller, etc. The reconstruction error in this case is strongly dominated by the error (perturbation) in the data at the location of the causality violation and the magnitude of the error is of the same order as the order of the perturbation. At the same time, the transfer function itself is very smooth, which ensures fast convergence of the Fourier series. The results are in a perfect agreement with the error estimate shown in Equations 33 and 34.

Another perturbation considered in testing is a cosine function a cos(20πx) added to Re H(x) while Im H(x) was kept unaltered. Adding a non-causal cosine perturbation makes the transfer function non-causal on the entire interval and higher reconstruction errors are expected everywhere. The result was that both errors E_{R}(x) and E_{I}(x) oscillate with the frequency and amplitude similar to those of the perturbation. For example, with a=10⁻¹⁰ these errors are of the order 6×10⁻¹¹. Increasing/decreasing a increases/decreases the magnitude of the error. To see how the level of a noise can be detected, set, for example, a=10⁻⁵ and compute the reconstruction errors E_{R}(x) and E_{I}(x) as the resolution increases. M is varied from 10 to 250, and the order of the errors was analyzed. The results are shown in Table 2. As can be seen, the reconstruction errors first decrease as the resolution (the number N of points) and the number M of Fourier coefficients increase until the error reaches the size of the perturbation, which happens at M=100, and after that the order of the error does not decrease further and levels off instead.

TABLE 2

| N | M | \|\| E_{R} \|\|_{∞}, \|\| E_{I} \|\|_{∞} | Al | M | \|\| E_{R} \|\|_{∞}, \|\| E_{I} \|\|_{∞} |
|---|---|---|---|---|---|
| 40 | 10 | ~10⁻¹ | 400 | 100 | ~7 × 10⁻⁶ |
| 100 | 25 | ~4 × 10⁻³ | 800 | 200 | ~7 × 10⁻⁶ |
| 200 | 50 | ~10⁻⁴ | 1000 | 250 | ~7 × 10⁻⁶ |

Table 2 illustrates the orders of errors E_{R}(x) and E_{I}(x) in example 6.1 with non-causal cosine perturbation a cos(20πx) with a=10⁻⁵ as M and N increase in proportion N=4M. With a smaller perturbation amplitude a, the error levels off at a larger value of M. For example, with a=10⁻¹⁰, the reconstruction errors stop decreasing at M=200.

### 6.2 Finite Element Model of a DRAM Package Example

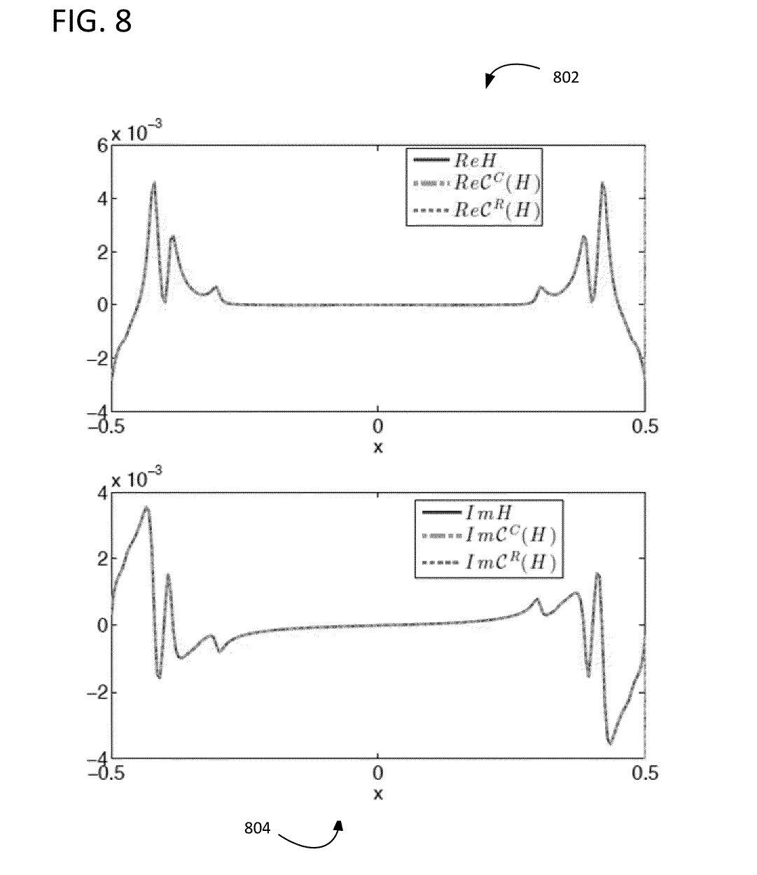

In this example, a scattering matrix S is used that was generated by a Finite Element Modeling (FEM) of a DRAM package. The package contains 110 input and output ports. The simulation process was performed for 100 equally spaced frequency points ranging from ωₘᵢₙ=0 to ωₘₐₓ=5 GHz. The data was expected to be causal but, perhaps, with some error due to limited accuracy of numerical simulations. For simplicity, the described approaches were applied to the S-parameter S(100,1) rather than the entire 110×110 S-matrix. The selected S-parameter H(ω)=S(100,1) relates the output signal from port 100 to the input signal at port 1 as a function of frequency ω. This approach can be extended to the entire S-matrix by applying the method to every element of the scattering matrix S. FIG. 8 shows plots 802 and 804 that illustrate H(x) with its causal Fourier continuations [symbol] ^{C}(H) and [symbol] ^{R}(H) in example 6.2 with M=100, N=199, and b=1.1.

In this test example, the number of samples in [−0.5,0.5] is fixed at N=2·100−1=199 (by symmetry), so to construct a causal Fourier continuation, M=100 Fourier coefficients are used and can only vary the length b of the extended region. Because the transfer function has oscillations and high slopes in the boundary region, a smaller value of b is used. A value of b=1.1 was found to be beneficial by trying a few different values of b∈(1,2). Slightly higher values of b give similar results while using too large b does not produce small enough error, most likely because the resolution is fixed and more data points would be needed to construct a causal continuation on a larger domain with sufficient resolution.

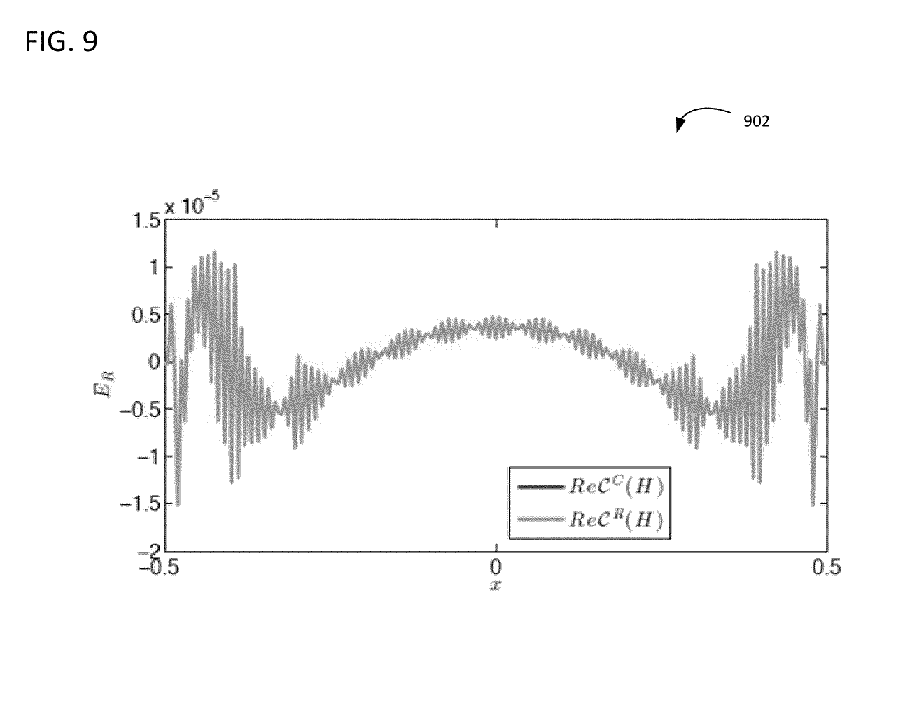

FIG. 9 shows plot 902 that illustrates the errors E_{R}(x) in approximation of S(100,1) in example 6.2 with N=199, M=100 and b=1.1. Errors E_{I}(x) have the same order of 10⁻⁵. This implies that the dispersion relations are satisfied within error on the order of 10⁻⁵. Since the data came from finite element simulations, the expected accuracy is to be on the order of 10⁻⁶ or 10⁻⁷ at least. To verify if the relatively large reconstruction errors comes from noise in the data or a causal Fourier series approximation error, data with N samples is used, then every other and every fourth samples, i.e. with N,

$$\frac{N - 1}{2} + 1 and \frac{N - 1}{4} + 1$$

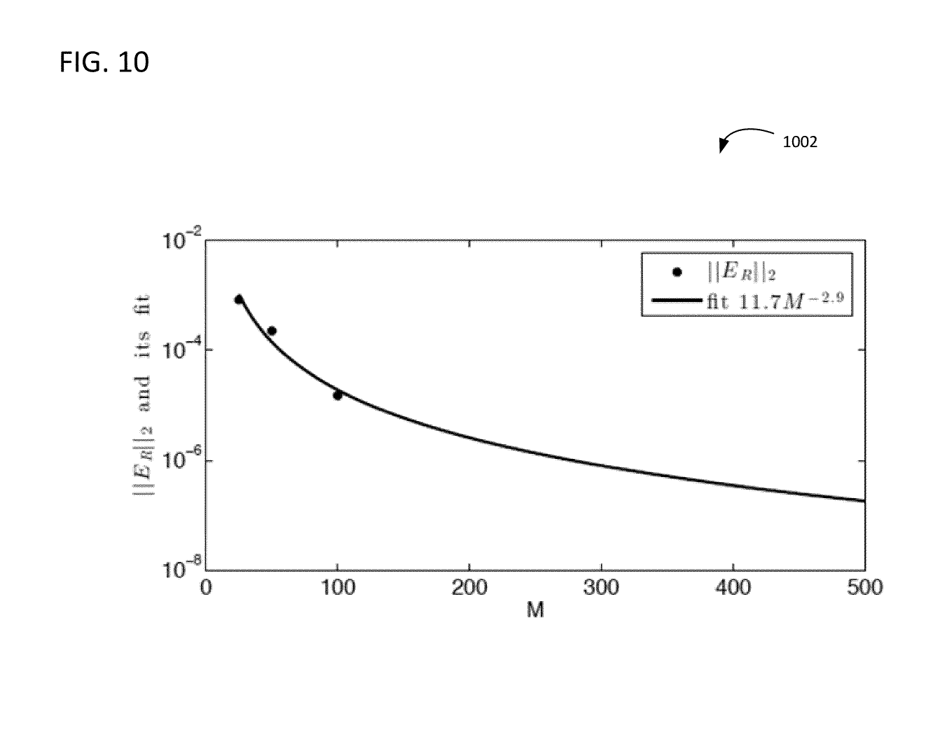

samples to find a model of the form (of Equation 37) CM^{a} using the least squares method. It was determined that both E_{R} and E_{I} decay approximately as [symbol] (M⁻³). These models were extrapolated to higher values of M as shown in FIG. 10, where the l₂ norms of actual reconstruction errors and fitted model curves are plotted in plot 1002. In plot 1002, the errors ∥E_{R}(x)∥₂ in approximation of S(100,1) in example 6.2 are plotted with N=199, 99, 49 and M=100, 50, 25, respectively, and b=1.1, together with their least squares fit: ∥E_{R}∥₂˜11.7M^{-2.9} and extrapolation for higher values of M. For ∥E_{I}(x)∥₂ it was found that ∥E_{I}∥₂˜23.5M^{-3.1}.

The extrapolated error curves indicate that the error may be decreased further if more frequency samples are available. In this case, it can be said that the transfer function H(x) satisfies dispersion relations within 10⁻⁵, i.e. the transfer function H(x) is causal within the error at most 10⁻⁵, and the causality violations, if present, are smaller than or at most on the order of 10⁻⁵. To determine the actual level of noise in the data, higher resolution of frequency responses would be needed.

### 6.3 Transmission Line Example

A uniform transmission line segment is considered here that has the following per-unit-length parameters: L=4.73 nH/cm, C=3.8 pF/cm, R=0.8 Ω/cm, G=0 and length [symbol] =10 cm. The frequency is sampled on the interval [0,5.0] GHz. The scattering matrix of the structure was computed using the MATLAB® function “rlgc2s.” Then, the element H(ω)=S₁₁(ω) is considered. Due to limitations of the model used in the function rlgc2s, a value of the transfer function at ω=0 (DC) cannot be obtained, but the transfer function can be sampled from any small nonzero frequency. It is typical for systems to have frequency response missing at low frequencies; this can occur either during measurements or simulations. However, the value of H(ω) at ω=0 is finite, because the magnitude of S₁₁ must be bounded by 1. Hence, this is a bandpass case. Once the number of points and the corresponding ωₘᵢₙ>0 is chosen, frequencies can be sampled from [ωₘᵢₙ, ωₘₐₓ]. Here, ωₘₐₓ=5.0 GHz is used. Using symmetry conditions reflects the values of the transfer function for negative frequencies as for the baseband case considered above. It is known that Im H(ω) equals 0 at ω=0 but Re H(ω) is to be computed. Since the value of Re H(ω) at ω=0 is unknown, the frequencies at which the values of the transfer function are available will have a gap at ω=0.

Nevertheless, the described approaches are still applicable since they do not require the data points to be equally spaced. In this example, better results are obtained, however, with smaller ωₘᵢₙ. Alternatively, a polynomial interpolation can be used to find a value of the real part of H(ω) at ω=0. The value of the imaginary part ImH(0)=0 by symmetry. This approach is not very accurate since it does not take into account causality when the polynomial interpolation of Re H(ω) is constructed, and it produces a larger error compared with just skipping the value at ω=0 and using spectral continuation approach directly. With the described approaches and M=1500, N=3000, b=4 a causal Fourier continuation was constructed that is accurate within 3×10⁻¹⁵.

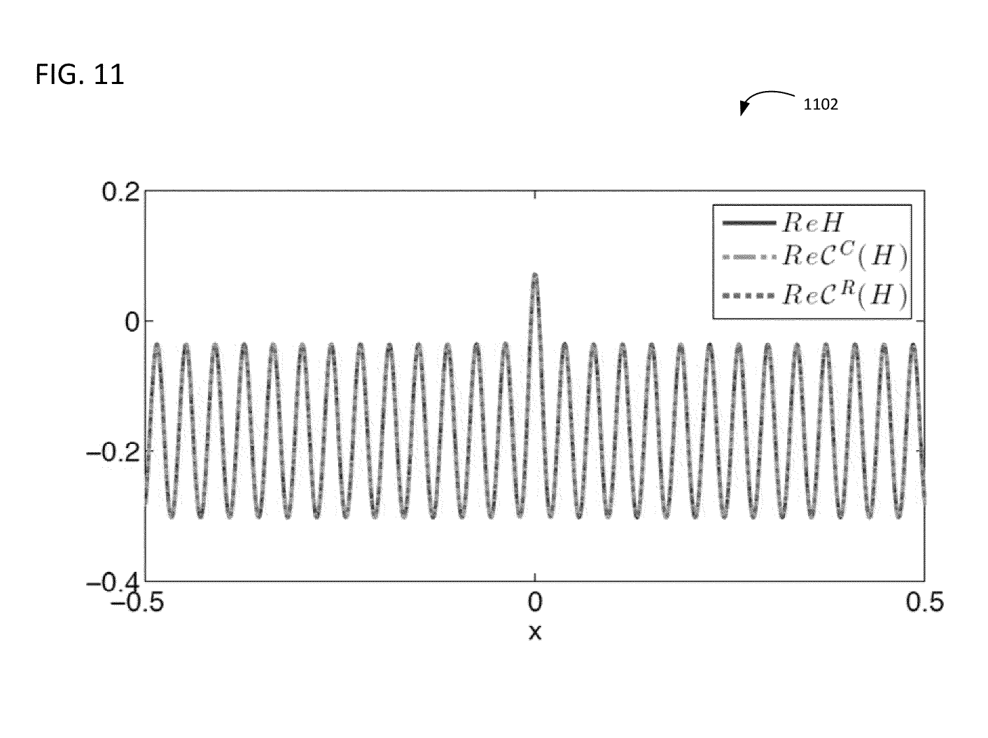

FIG. 11 shows plot 1102, illustrating (the real parts of) transfer function H(x) and its causal Fourier continuations [symbol] ^{C}(H) and [symbol] ^{R}(H) in example 6.3 with M=1500, N=3000, b=4. Agreement for Im H(ω) is similar. With smaller values of ωₘₐₓ, it is enough to use smaller values of M and N in the same proportion 2M=N to get the same order of accuracy. For example, to get an error in approximation of the transfer function on the original interval at the order of 10⁻¹⁴ and ωₘₐₓ=3.0 GHz, it is enough to use M=750 and N=1500, while for ωₘₐₓ=1 GHz, M=250 and N=500 could be used. In this case, more data points would be needed to have the same resolution on the longer domain.

Computations discussed herein were done using MATLAB® on an Apple® MacBook Pro® computer with a 2.93 GHz Intel Core® 2 Duo Processor and 4 GB RAM. The CPU times (in seconds) for computing the SVD, minimum norm solution of a linear system using the least squares method as well as overall CPU time for constructing a causal Fourier continuation with M varying from 50 to 1500 with N=2M are shown below in Table 3.

TABLE 3

| | | CPU time | CPU time | CPU time |
|---|---|---|---|---|
| N | M | (SVD) | (minnmsvd) | (continuation) |
| 100 | 50 | 0.0030 | 3.4579e−5 | 0.0276 |
| 200 | 100 | 0.0094 | 8.4246e−4 | 0.0543 |
| 500 | 250 | 0.1245 | 0.0057 | 0.3574 |
| 1000 | 500 | 0.7818 | 0.0108 | 1.5224 |
| 2000 | 1000 | 6.5252 | 0.0455 | 9.3935 |
| 3000 | 1500 | 29.7123 | 0.0814 | 36.8826 |

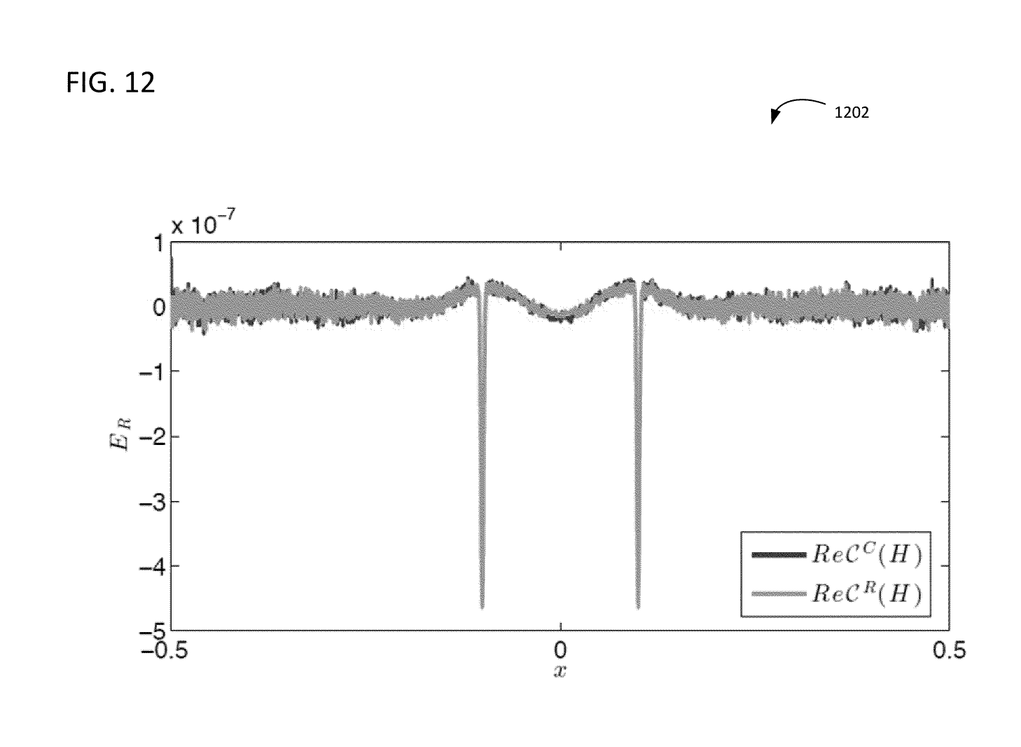

A Gaussian perturbation is then imposed on the transfer function as in example 6.1 with amplitude a=10⁻⁶ to model a causality violation located at x₀=0.1 with the standard deviation σ=10⁻²/6, so that the “support” of the Gaussian is approximately 10⁻² or 1/10 of the entire bandwidth. FIG. 12 shows plot 1202 illustrating Errors E_{R}(x) in example 6.3 with M=1500, N=3000, and b=4, and non-causal Gaussian perturbation with a=10⁻⁶, σ=10⁻²/6, centered at x₀=0.1. This results in the error having very pronounced spikes, shown in plot 1202, of magnitude 4.5×10⁻⁷ in both Re H and Im H at the locations of the perturbation, while as before, the error on the rest of the interval is approximately 10 times smaller. Reliable detection of a causality violation was demonstrated here up to an amplitude of a=5×10⁻¹⁴. The errors E_{I}(x) have similar spikes at causality violation locations.

Using the described approaches, boundary artifacts are able to be removed and detection of very small localized infinitely smooth (Gaussian) causality violations can be realized. The resolution of data also affects results since the number N of collocation points at which frequency responses are available dictates the number M of Fourier coefficients with N=2M, and, hence, the sensitivity of the described approaches to causality violations. For instance, in the above example with N=250 (125 points in [0,0.5]), a causality violation can be detected with a=5×10⁻⁷, whereas N=500 and N=1000 are capable of detecting violations with a=10⁻¹² and a=5×10⁻¹³, respectively. Results indicate it is more difficult to detect wide causality violations. As the “support” 6σ of the Gaussian increases, the spikes in the reconstruction errors become wider and shorter, and eventually it is not possible to determine the location of the causality violation since the error at the causality violation locations has the same order as the error on the rest of the interval. For 6σ≦0.1, the spikes in the errors are still observable, whereas for a bigger value 6σ≧0.2, the reconstruction errors are uniform. Increasing the resolution of the data does not decrease the reconstruction errors, that indicates the presence of causality violations of the order of reconstruction errors.

### 6.4 Delayed Gaussian Example

Here, the performance of the described approaches is tested with an example of a delayed Gaussian function to check the causality of interconnects through the minimum-phase and all-pass decomposition. An impulse response function is considered that is modeled by a

Gaussian with the center of the peak t_{d} and standard deviation σ:

$$h ( t , {t}_{d} ) = exp [ - \frac{{( t - {t}_{d} )}^{2}}{2 {σ}^{2}} ] . \qquad ( 45 )$$

If t_{d}=0, the Gaussian function h(t,0) is even, so it cannot be causal. As t_{d} increases, the center of the peak moves to the right and for t_{d}>3σ the impulse response function h(t,t_{d}) can be gradually made causal. The corresponding transfer function is

H(ω,t_{d})=exp[−2(πωσ)²−2iπωt_{d}] (46)

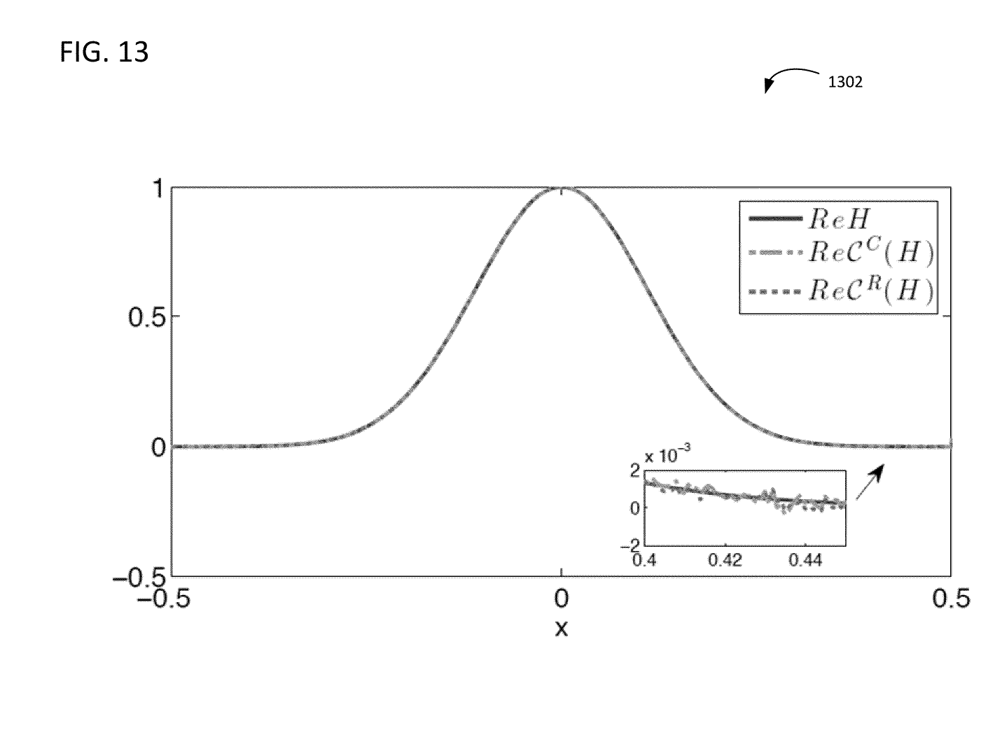

which is a periodic function damped by an exponentially decaying function. Two regimes are considered here. One has value of t_{d}<3σ, so that the transfer function H(ω,t_{d}) is non-causal. In the second regime, the delay t_{d}>3σ is big enough to make the transfer function H(ω,t_{d}) causal. Then, b=2, σ=2 are fixed, and ω is sampled from the interval [0,3.6×10⁸] Hz and considered first the case with t_{d}=0.1σ. FIG. 13 shows plot 1302 illustrating noncausal transfer function H(ω,t_{d}) of example 6.4 and its Fourier continuations [symbol] ^{C}(H) and [symbol] ^{R}(H) with M=250, N=500, b=2, t_{d}=0.1σ (only real parts are shown). It can be clearly seen that the Fourier continuations do not match Re H well.

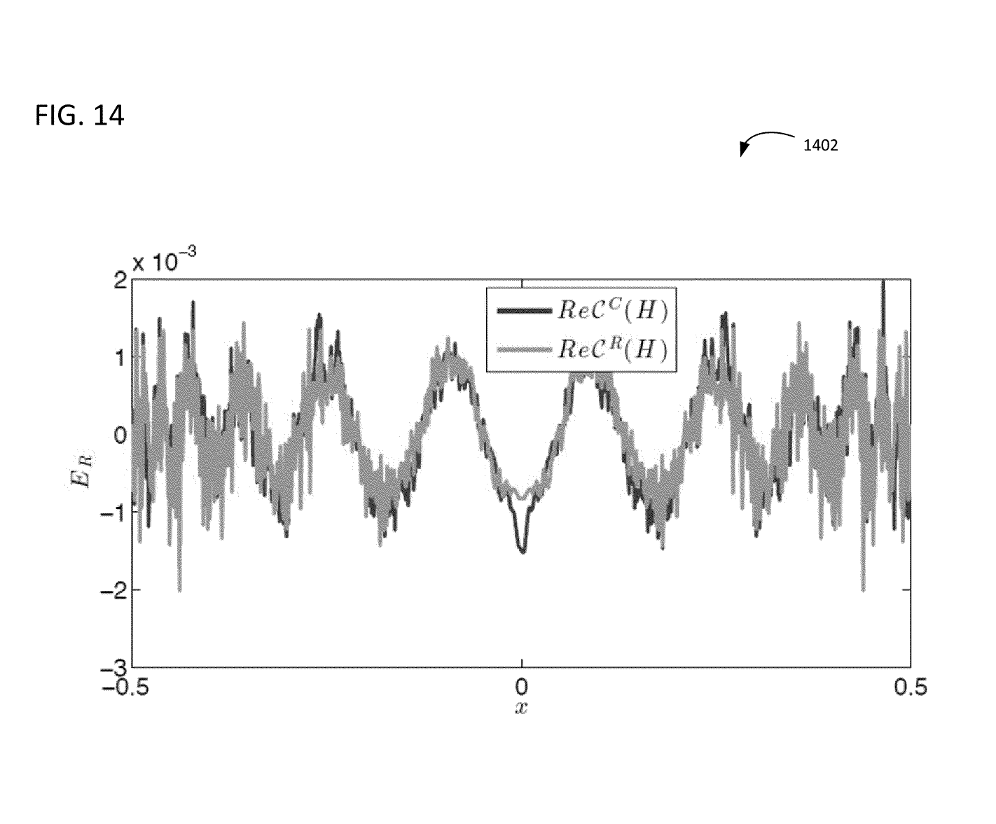

Instead, there are visible high frequency oscillations throughout the domain as confirmed by analyzing the reconstruction errors E_{R}(x). FIG. 14 shows plot 1402 illustrating Errors E_{R}(x) between the noncausal transfer function H(ω,t_{d}) and its causal Fourier continuations [symbol] ^{C}(H) and [symbol] ^{R}(H) in example 6.4 with M=250, N=500, b=2, t_{d}=0.1σ. Errors E_{I}(x) have the same order. With M=250, N=500, the magnitude of the errors is about 2×10⁻³, as is shown in plot 1402. When N is increased in proportion N=2M, the error increases slightly. For example, with M=1000, N=2000, the errors are about 4×10⁻³. Varying the length b of the extended domain does not decrease the magnitude of the error. This is in agreement with the error estimate shown in Equations 33 and 34 since in this case the reconstruction error is dominated by causality violations. Results for E_{I}(x) are similar.

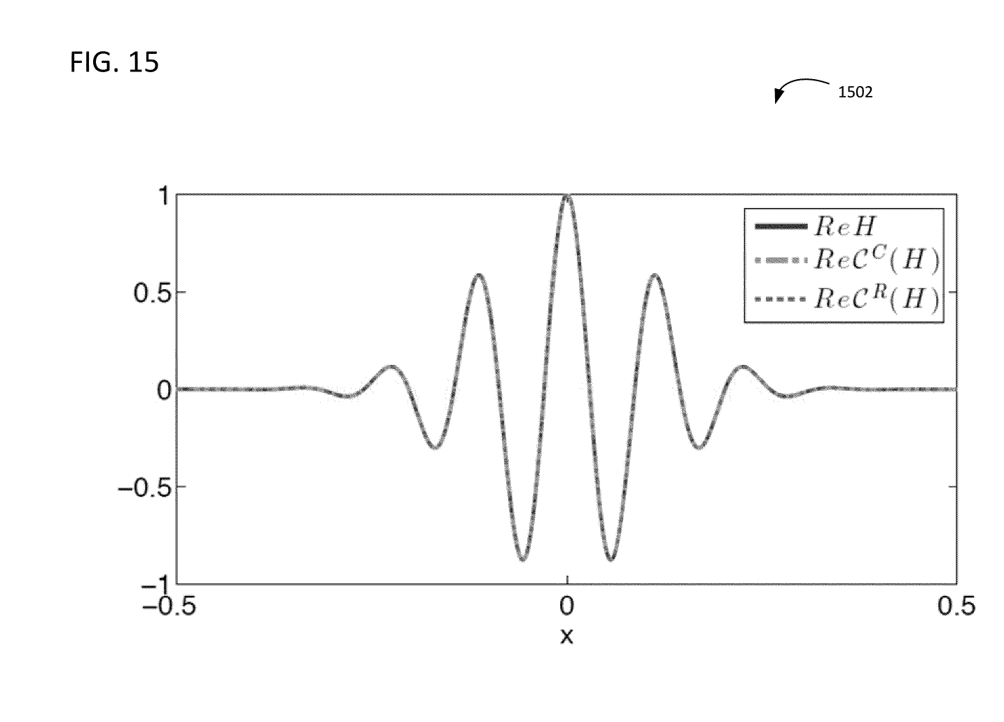

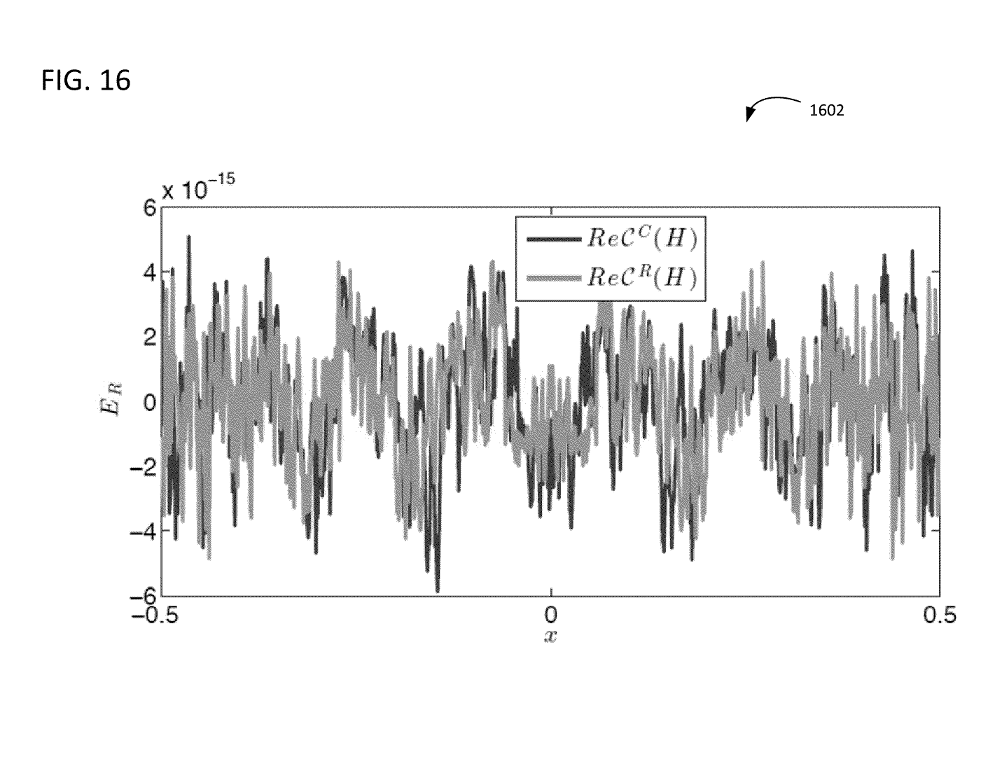

In a second test, t_{d}=6σ, which should give a causal transfer function. FIG. 15 shows plot 1502 illustrating the causal transfer function H(ω,t_{d}) in example 6.4 and its Fourier continuation with M=250, N=500, b=2, t_{d}=6a (real parts are shown). FIG. 16 shows plot 1602 illustrating errors E_{R}(x) between the causal transfer function H(w,t_{d}) and its causal Fourier continuation in example 6.4 with M=250, N=500, b=2, t_{d}=6σ. Errors E_{I}(x) have the same order. Both reconstruction errors E_{R}(x) and E_{I}(x) drop to the order of 2×10⁻¹⁵ as shown in plot 1602.

In this case, the transfer function is causal and infinitely smooth, so the error in approximation of such function with a causal Fourier series decays quickly even for moderate values of M. A gradual change of the non-causal Gaussian function into a causal function is observed as t_{d} increases. With t_{d}=γσ and varying values γ=1, 2, 4, and 5 it was found that the l_{∞} norms of both errors E_{R} and E_{I} are 5×10⁻⁶, 10⁻⁷, 3×10⁻¹² and 10⁻¹⁴, respectively, i.e. the error decays as t_{d} increases as expected.

Described approaches for verification and enforcement, if necessary, of causality of bandlimited tabulated frequency responses, are presented that can be employed before the data are used for macromodeling. The described approaches are based on the Kramers-Krönig dispersion relations and a construction of periodic, causal Fourier continuations (e.g., through an SVD approach). This can be done by calculating accurate causal Fourier series approximations of transfer functions, not periodic in general, and allowing the causal Fourier series to be periodic in an extended domain. The causality is imposed directly on Fourier coefficients using dispersion relations that require real and imaginary parts of a causal function to be a Hilbert transform pair.

The described approaches eliminates the necessity of approximating the behavior of the transfer function at infinity, which is known to be a source of significant errors in computation of the Hilbert transform defined on an infinite domain (or semi-infinite due to spectrum symmetry) with data available only on a finite bandwidth. In addition, the described approaches do not require direct numerical evaluation of the Hilbert transform. The Fourier coefficients can be computed by solving an oversampled regularized least squares problem via a truncated SVD method to have the ill-conditioning of the system under control. Causal Fourier continuations even with a moderate number of Fourier coefficients are typically oscillatory in the extended domain but this does not essentially affect the quality of reconstruction of the transfer function on the original frequency domain. The length of the extended domain may be tuned to find more optimal values that would allow decreasing overall reconstruction errors.

The error analysis performed for the proposed method unbiases the error of approximation of a transfer function with a causal Fourier series, the error due to truncation of singular values from the causality violations, i.e. a noise or approximation errors in data obtained from measurements or numerical simulations, respectively. The obtained estimates for upper bounds of these errors can be used to verify causality of the given frequency responses. The described approaches are applicable to both baseband and bandpass regimes and do not require data points to be equally spaced. The described approaches show high accuracy and robustness and are capable of detecting very small localized causality violations of the amplitude close to the machine precision. The described approaches were applied to several analytic and simulated examples with and without causality violations, and the results demonstrate an excellent performance of the described approaches in agreement with obtained error estimates.

### 7. Examples of Computing Environments

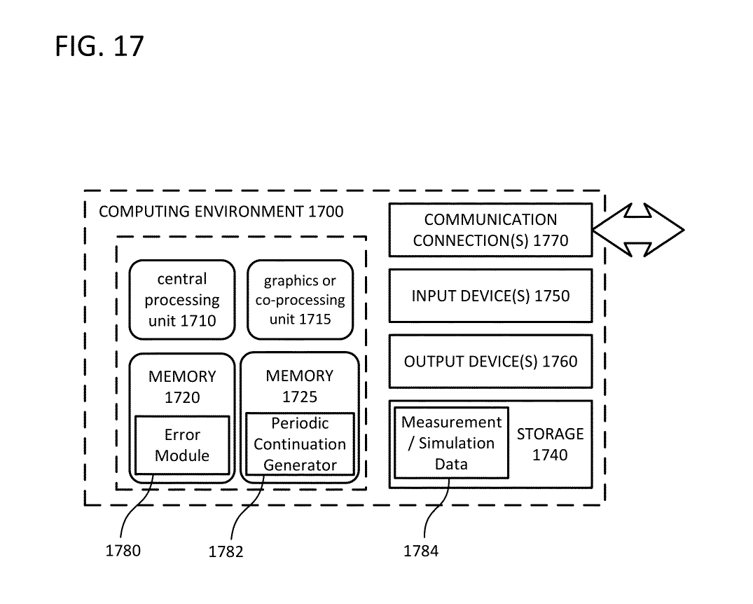

FIG. 17 depicts a generalized example of a suitable computing environment 1700 in which the described innovations may be implemented. The computing environment 1700 is not intended to suggest any limitation as to scope of use or functionality, as the innovations may be implemented in diverse general-purpose or special-purpose computing systems. For example, the computing environment 1700 can be any of a variety of computing devices (e.g., desktop computer, laptop computer, server computer, tablet computer, media player, gaming system, mobile device, etc.)

With reference to FIG. 17, the computing environment 1700 includes one or more processing units 1710, 1715 and memory 1720, 1725. In FIG. 17, this basic configuration 1730 is included within a dashed line. The processing units 1710, 1715 execute computer-executable instructions. A processing unit can be a general-purpose central processing unit (CPU), processor in an application-specific integrated circuit (ASIC) or any other type of processor. In a multi-processing system, multiple processing units execute computer-executable instructions to increase processing power.

For example, FIG. 17 shows a central processing unit 1710 as well as a graphics processing unit or co-processing unit 1715. The tangible memory 1720, 1725 may be volatile memory (e.g., registers, cache, RAM), non-volatile memory (e.g., ROM, EEPROM, flash memory, etc.), or some combination of the two, accessible by the processing unit(s). The memory 1720, 1725 stores software implementing the approaches described herein, in the form of computer-executable instructions suitable for execution by the processing unit(s). For example, memory 1720 can store instructions for implementing an error module 1780 similar to error module 312 of FIG. 3. Memory 1725 can store, for example, instructions for implementing a periodic continuation generator 1782 similar to periodic continuation generator 310 of FIG. 3.

A computing system may have additional features. For example, the computing environment 1700 includes storage 1740, one or more input devices 1750, one or more output devices 1760, and one or more communication connections 1770. An interconnection mechanism (not shown) such as a bus, controller, or network interconnects the components of the computing environment 1700. Typically, operating system software (not shown) provides an operating environment for other software executing in the computing environment 1700, and coordinates activities of the components of the computing environment 1700.

The tangible storage 1740 may be removable or non-removable, and includes magnetic disks, magnetic tapes or cassettes, CD-ROMs, DVDs, or any other medium which can be used to store information and which can be accessed within the computing environment 1700. Storage 1740 can store instructions for software implementing one or more innovations described herein. Storage 1740 can also store data such as measurement/simulation data 1784.

The input device(s) 1750 may be a touch input device such as a keyboard, mouse, pen, or trackball, a voice input device, a scanning device, or another device that provides input to the computing environment 1700. For video encoding, the input device(s) 1750 may be a camera, video card, TV tuner card, or similar device that accepts video input in analog or digital form, or a CD-ROM or CD-RW that reads video samples into the computing environment 1700. The output device(s) 1760 may be a display, printer, speaker, CD-writer, or another device that provides output from the computing environment 1700.

The communication connection(s) 1770 enable communication over a communication medium to another computing entity. The communication medium conveys information such as computer-executable instructions, audio or video input or output, or other data in a modulated data signal. A modulated data signal is a signal that has one or more of its characteristics set or changed in such a manner as to encode information in the signal. By way of example, and not limitation, communication media can use an electrical, optical, RF, or other carrier.

Although the operations of some of the disclosed methods are described in a particular, sequential order for convenient presentation, it should be understood that this manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed methods can be used in conjunction with other methods.

Any of the disclosed methods can be implemented as computer-executable instructions stored on one or more computer-readable storage media (e.g., one or more optical media discs, volatile memory components (such as DRAM or SRAM), or nonvolatile memory components (such as flash memory or hard drives)) and executed on a computer (e.g., any commercially available computer, including smart phones or other mobile devices that include computing hardware). The term computer-readable storage media does not include communication connections, such as signals and carrier waves. Any of the computer-executable instructions for implementing the disclosed techniques as well as any data created and used during implementation of the disclosed embodiments can be stored on one or more computer-readable storage media. The computer-executable instructions can be part of, for example, a dedicated software application or a software application that is accessed or downloaded via a web browser or other software application (such as a remote computing application). Such software can be executed, for example, on a single local computer (e.g., any suitable commercially available computer) or in a network environment (e.g., via the Internet, a wide-area network, a local-area network, a client-server network (such as a cloud computing network), or other such network) using one or more network computers.

For clarity, only certain selected aspects of the software-based implementations are described. Other details that are well known in the art are omitted. For example, it should be understood that the disclosed technology is not limited to any specific computer language or program. For instance, the disclosed technology can be implemented by software written in C++, Java, Perl, JavaScript, Adobe Flash, or any other suitable programming language. Likewise, the disclosed technology is not limited to any particular computer or type of hardware. Certain details of suitable computers and hardware are well known and need not be set forth in detail in this disclosure.

It should also be well understood that any functionality described herein can be performed, at least in part, by one or more hardware logic components, instead of software. For example, and without limitation, illustrative types of hardware logic components that can be used include Field-programmable Gate Arrays (FPGAs), Application-specific Integrated Circuits (ASICs), Application-specific Standard Products (ASSPs), System-on-a-chip systems (SOCs), Complex Programmable Logic Devices (CPLDs), etc.

Furthermore, any of the software-based embodiments (comprising, for example, computer-executable instructions for causing a computer to perform any of the disclosed methods) can be uploaded, downloaded, or remotely accessed through a suitable communication means. Such suitable communication means include, for example, the Internet, the World Wide Web, an intranet, software applications, cable (including fiber optic cable), magnetic communications, electromagnetic communications (including RF, microwave, and infrared communications), electronic communications, or other such communication means.

The disclosed methods, apparatus, and systems should not be construed as limiting in any way. Instead, the present disclosure is directed toward all novel and nonobvious features and aspects of the various disclosed embodiments, alone and in various combinations and subcombinations with one another. The disclosed methods, apparatus, and systems are not limited to any specific aspect or feature or combination thereof, nor do the disclosed embodiments require that any one or more specific advantages be present or problems be solved.

In view of the many possible embodiments to which the principles of the disclosed invention may be applied, it should be recognized that the illustrated embodiments are only preferred examples of the invention and should not be taken as limiting the scope of the invention. Rather, the scope of the invention is defined by the following claims. We therefore claim as our invention all that comes within the scope of these claims.

What is claimed is:

1. One or more computer-readable media storing computer-executable instructions for evaluating causality, the evaluating comprising:
receiving an initial transfer function representing the behavior of electrical interconnects of a system over an initial frequency range;
constructing a causal, periodic continuation based on the initial transfer function and one or more causality conditions, the continuation being periodic over an extended frequency range that is larger than the initial frequency range;
comparing, at a plurality of frequencies, values for the initial transfer function and values for the continuation; and
assessing causality of the initial transfer function based on the comparing.

2. The one or more computer-readable media of claim 1, wherein the initial transfer function is based on at least one of simulation results for the system or measurements of the system.

3. The one or more computer-readable media of claim 1, wherein the initial transfer function represents one of admittance parameters of the system, impedance parameters of the system, or scattering parameters of the system.

4. The one or more computer-readable media of claim 1, wherein the system comprises at least one of an integrated circuit or packaging of an integrated circuit.

5. The one or more computer-readable media of claim 1, wherein the one or more causality conditions comprise dispersion relations represented through a Hilbert transform.

6. The one or more computer-readable media of claim 1, wherein constructing the causal, periodic continuation function comprises:
approximating the initial transfer function as a Fourier series; and
determining values for Fourier coefficients of the Fourier series such that the one or more causality conditions are satisfied.

7. The one or more computer-readable media of claim 6, wherein the values for the Fourier coefficients are also determined by requiring values for the continuation to match values of the initial transfer function for a plurality of frequencies.

8. The one or more computer-readable media of claim 6, wherein determining the values for the Fourier coefficients comprises applying a truncated singular value decomposition approach to control ill-conditioning.

9. The one or more computer-readable media of claim 1, wherein assessing causality comprises upon determining that an error based on the comparing is below a threshold, determining that the initial transfer function representing the behavior of the electrical interconnects of the system is causal.

10. The one or more computer-readable media of claim 9, wherein the threshold is selected based on at least one of smoothness of the initial transfer function, a number of Fourier coefficients in the continuation, or noise in data on which the initial transfer function is based.

11. The one or more computer-readable media of claim 9, wherein the error is determined as at least one of (i) a first error that is the difference between a real part of the initial transfer function and a real part of the continuation or (ii) a second error that is the difference between an imaginary part of the initial transfer function and an imaginary part of the continuation.

12. The one or more computer-readable media of claim 1, wherein assessing causality comprises upon determining that an error based on the comparing is above a threshold, determining that at least one of: (i) the initial transfer function representing the behavior of the electrical interconnects is non-causal or (ii) a number of values for the initial transfer function at different frequencies has resulted in error from discretization being above the threshold.

13. One or more computers implementing a system for evaluating causality, the system comprising:
a periodic continuation generator configured to:
based on (i) an initial transfer function representing the behavior of electrical interconnects of an electronic system over an initial frequency range and (ii) one or more causality conditions, determine a causal, periodic continuation over an extended frequency range that is larger than the initial frequency range; and
an error module configured to:
assess causality of the initial transfer function by determining an error of the continuation with respect to the initial transfer function.

14. The one or more computers of claim 13, wherein the periodic continuation generator is configured to determine the causal, periodic continuation by:
approximating the initial transfer function as a Fourier series over the extended frequency range; and
determining values for Fourier coefficients of the Fourier series by:
imposing the one or more causality conditions in the frequency domain; and
determining the values for the Fourier coefficients through a least squares approach such that (i) the one or more causality conditions are satisfied and (ii) for a plurality of frequencies within the initial frequency range, values of the initial transfer function correspond to values for the continuation.

15. The one or more computers of claim 13, wherein the error module is further configured to assess causality by comparing the error to a threshold, wherein when the error is below the threshold, the error module determines that the initial transfer function representing the behavior of the electrical interconnects of the electronic system is causal, and wherein when the error is above the threshold, determining that at least one of: (i) the initial transfer function representing the behavior of the electrical interconnects of the electronic system is non-causal or (ii) a resolution of data upon which the initial transfer function is based is low enough to result in error being above the threshold.

16. The one or more computers of claim 13, wherein the electronic system comprises an integrated circuit, and wherein the initial transfer function represents at least one of simulation results for or measurements of admittance, impedance, or scattering parameters for the electrical interconnects in the integrated circuit.

17. A computer-implemented method for evaluating causality, the evaluating comprising:
obtaining an initial transfer function representing the behavior of electrical interconnects of an electronic system over an initial frequency range;
determining a continuation that is both causal and periodic over an extended frequency range by:
representing the initial transfer function as a Fourier series over the extended frequency range;
establishing a causality condition in the frequency domain, the causality condition specifying that an imaginary part of the continuation is a Hilbert transform of a negative of a real part of the continuation; and
determining values for Fourier coefficients for the Fourier series such that (i) the causality condition is satisfied and (ii) for a plurality of frequencies within the initial frequency range, values of the continuation correspond to values for the initial transfer function;
determining an error of the continuation with respect to the initial transfer function; and
assessing causality of the initial transfer function based on the error.

18. The computer-implemented method of claim 17, wherein assessing the error comprises comparing the error to a threshold, wherein when the error is below the threshold, the initial transfer function is causal, and wherein when the error is above the threshold, the initial transfer function is either non-causal, or a number of values obtained for the initial transfer function at different frequencies has resulted in the error being a discretization error above the threshold.

19. The computer-implemented method of claim 17, wherein the initial transfer function represents at least one of simulation results for or measurements of admittance, impedance, or scattering parameters for the electrical interconnects in the electronic system.

20. The computer-implemented method of claim 17, further comprising upon determining that the initial transfer function is non-causal based on the assessing, replacing the initial transfer function with the continuation.
